(19) United States
(12) Patent Application Publication
(10) Pub. No.: US 2026/0198136 A1
(43) Pub. Date: Jul. 9, 2026

(54) GROUP III NITRIDE SEMICONDUCTOR LIGHT-EMITTING DEVICE

(71) Applicant: Soft-Epi Inc., Gyeonggi-do (KR)

(72) Inventor: Sung Min HWANG, Gyeonggi-do (KR)

(21) Appl. No.: 19/124,004

(22) PCT Filed: Oct. 26, 2023
(86) PCT No.: PCT/KR2023/016773

§ 371 Date: Apr. 24, 2025

(30) Foreign Application Priority Data
Oct. 27, 2022 (KR) 10-2022-0140126
Jan. 16, 2023 (KR) 10-2023-0006266
Mar. 9, 2023 (KR) 10-2023-0031246
Jun. 21, 2023 (KR) 10-2023-0079787
Jun. 21, 2023 (KR) 10-2023-0079793
Jun. 21, 2023 (KR) 10-2023-0079794

(51) Int. Cl. H10H 20/812; H10H 20/825

(52) U.S. Cl. CPC H10H 20/812; H10H 20/8252

(57) ABSTRACT

The disclosure relates to a III-nitride semiconductor light emitting device comprising: a first semiconductor region having a first conductivity; a second semiconductor region having a second conductivity different from the first conductivity; and an active region interposed between the first and second semiconductor regions and generating light through electron-hole recombination wherein the active region includes a quantum well layer with an indium (In) content (x) corresponding to an emission wavelength below 500 nm and emits light with a wavelength exceeding 600 nm.

### FIELD OF THE INVENTION

The disclosure generally relates to a III-nitride semiconductor light emitting device. In particular, it relates to a III-nitride semiconductor light emitting device that emits red light and a method for emitting red light using the same. Here, the III-nitride semiconductor is composed of a compound of Al(x)Ga(y)In(1-x-y)N (0≤x≤1, 0≤y≤1, 0≤x+y≤1.

### BACKGROUND OF THE INVENTION

This section provides background information related to the disclosure which is not necessarily

Up to date, commercially available semiconductor light emitting devices (e.g., LEDs, LDs) that emit light in the red color range are made of AlGaInP-based compound semiconductors, but recently those emitting light in yellow, amber, orange, red, and infrared ranges have been spotlighted.

FIG. 1 shows an example of a conventional III-nitride semiconductor light emitting device that emits light in a red color range. The semiconductor light emitting device includes a growth substrate 10 (e.g., a patterned C-plane sapphire substrate (PSS)), a buffer region 20 (e.g., un-doped GaN (2 μm) formed on a seed layer (GaN grown at a low temperature), an n-side contact region 30 (e.g., Si-doped GaN (2-8 μm) and Si-doped Al_{0.03}Ga_{0.97}N (1 μm)), a superlattice region 31 (e.g., 15 cycle GaN (6 nm)/In_{0.08}Ga_{0.92}N (2 nm)), 15 nm-thick Si-doped GaN 32, an In-deplete quantum well structure 41 (e.g., a quantum well made of In_{0.2}Ga_{0.8}N (2 nm) and a barrier made of GaN (2 nm)/Al_{0.13}Ga_{0.87}N (18 nm)/GaN (3 nm)), a red light emitting active region 42 (e.g., a quantum well made of InGaN (2.5 nm)—a barrier made of AlN (1.2 nm)/GaN (2 nm)/Al_{0.13}Ga_{0.87}N (18 nm)/GaN (3 nm))—a quantum well made of InGaN (2.5 nm)—a barrier made of AlN (1.2 nm)/GaN (23 nm)), a 15 nm thick GaN layer 43, a p-side region 50 (e.g., Mg-doped GaN (100 nm) and p-GaN:Mg (10 nm)), a current spreading electrode 60 (e.g., ITO), a first electrode 70 (e.g., Cr/Ni/Au), and a second electrode 80 (e.g., Cr/Ni/Au) (Article titled “633-nm InGaN-based red LEDs grown on thick underlying GaN layers with reduced in-plane residual stress”, Applied Physics Letters, April 2020).

U.S. Pat. No. 10,396,240 also discloses a semiconductor light emitting device that emits light in a red range using an InGaN active region.

FIG. 50 illustrates an example of a III-nitride semiconductor light emitting device presented in Korean Patent Publication No. 2011-0037616. The III-nitride semiconductor light emitting device 100 includes a first semiconductor light emitting unit 110 and a second semiconductor light emitting unit 120. The first semiconductor light emitting unit 110 includes a first semiconductor region 110a (e.g., an n-side contact region), a first active region 110b (e.g., a red light emitting active region), a second semiconductor region 110c (e.g., a p-side contact region), a first electrode 113a electrically connected to the first semiconductor region 110a, and a second electrode 113b electrically connected to the second semiconductor region 110c. The second semiconductor light emitting unit 120 includes a first semiconductor region 120a (e.g., an n-side contact region), a second active region 120b (e.g., a green light emitting active region), a second semiconductor region 120c (e.g., a p-side contact region), a first electrode 123a electrically connected to the first semiconductor region 120a, and a second electrode 123b electrically connected to the second semiconductor region 120c. By enabling the first active region 110b and the second active region 120b to emit light in complementary colors, the device can achieve an overall white light emission.

FIG. 51 illustrates another example of a III-nitride semiconductor light emitting device presented in Korean Patent Publication No. 2011-0037616. The III-nitride semiconductor light emitting device 200 includes a first semiconductor light emitting unit 110, a second semiconductor light emitting unit 120, and a third semiconductor light emitting unit 230. The first semiconductor light emitting unit 110 includes a first semiconductor region 110a (e.g., an n-side contact region), a first active region 110b (e.g., a red light emitting active region), a second semiconductor region 110c (e.g., a p-side contact region), a first electrode 113a electrically connected to the first semiconductor region 110a, and a second electrode 113b electrically connected to the second semiconductor region 110c. The second semiconductor light emitting unit 120 includes a first semiconductor region 120a (e.g., an n-side contact region), a second active region 120b (e.g., a green light emitting active region), a second semiconductor region 120c (e.g., a p-side contact region), a first electrode 123a electrically connected to the first semiconductor region 120a, and a second electrode 123b electrically connected to the second semiconductor region 120c. The third semiconductor light emitting unit 230 includes a first semiconductor region 230a (e.g., an n-side contact region), a third active region 230b (e.g., a blue light emitting active region), a second semiconductor region 230c (e.g., a p-side contact region), a first electrode 233a electrically connected to the first semiconductor region 230a, and a second electrode 233b electrically connected to the second semiconductor region 230c. A first insulation layer 130 (e.g., SiN₂, SiO₂, AlN, etc.) is provided between the first semiconductor light emitting unit 110 and the second semiconductor light emitting unit 120 for electrical insulation. Similarly, a second insulation layer 240 (e.g., SiN₂, SiO₂, AlN, etc.) is provided between the second semiconductor light emitting unit 120 and the third semiconductor light emitting unit 230 for electrical insulation. A technique for forming the first insulation layer 130 and the second insulation layer 240 using high-resistance Mg-doped GaN is presented in Japanese Patent Publication No. 1996-274369. This technology facilitates the growth of semiconductor light emitting units 110, 120, and 230 within a single apparatus (MOCVD equipment). While multiple references, including U.S. Pat. No. 5,684,309, mention the fabrication of active regions 110b, 120b, and 230b using InGaN, this approach has not yet been commercially implemented.

### SUMMARY OF THE INVENTION

This section provides a general summary of the disclosure and is not a comprehensive disclosure of its full scope or all of its features.

One aspect of the disclosure provides a method for manufacturing a III-nitride semiconductor light-emitting structure that emits red light with a peak wavelength of 600 nm or more, comprising the steps of growing a first superlattice region formed by the repeated stacking of a first sublayer and a second sublayer, and growing an active region on the first superlattice region, which consists of a third sublayer made of an Al-containing III-nitride semiconductor with a first bandgap energy, a fourth sublayer made of an In-containing III-nitride semiconductor with a second bandgap energy smaller than the first bandgap energy, and a fifth sublayer made of an Al-containing III-nitride semiconductor with a third bandgap energy larger than the second bandgap energy. During the active region growth step, setting the In content of the fourth sublayer so that it emits light with a peak wavelength of 600 nm or less when the third and fifth sublayers are GaN, and adjusting the Al content in the third and fifth sublayers so that the fourth sublayer emits red light with a peak wavelength of 600 nm or more.

According to another aspect of the disclosure, there is provided a III-nitride semiconductor light emitting device comprising an active region that emits red light and a semi-polar plane positioned below the active region for its growth.

According to another aspect of the disclosure, there is provided a method for measuring a III-nitride semiconductor light-emitting device, comprising the steps of forming a first III-nitride semiconductor light-emitting unit with an active region that emits first light, forming a second III-nitride semiconductor light-emitting unit that emits second light different from the first light, forming a conductive pad extending from the first semiconductor region to the second III-nitride semiconductor light-emitting unit, and using first and second measurement electrodes to measure the electroluminescence (EL) of the first III-nitride semiconductor light-emitting unit.

According to another aspect of the disclosure, there is provided a method for manufacturing a III-nitride semiconductor light-emitting device comprising selectively growing a first semiconductor light-emitting unit using a first opening, selectively growing a second semiconductor light-emitting unit using a larger second opening, and configuring the first semiconductor light-emitting unit to emit blue light while the second semiconductor light-emitting unit emits a longer wavelength light than blue.

According to another aspect of the disclosure, there is provided a method for manufacturing a III-nitride semiconductor light-emitting device in which a first semiconductor light-emitting unit is selectively grown using a first opening, a second semiconductor light-emitting unit is selectively grown using a larger second opening, the first and second openings are formed in a single growth mask, and the growth mask serves as a passivation layer while at least one electrode is formed to supply power.

According to another aspect of the disclosure, there is provided a III-nitride semiconductor light emitting device comprising a first semiconductor region having a first conductivity, a second semiconductor region having a second conductivity different from the first conductivity, and an active region interposed between the first and second semiconductor regions, where the active region emits light through electron-hole recombination. The active region includes a quantum well layer with an indium (In) content (x) corresponding to an emission wavelength below 500 nm and an emission region that emits light with a wavelength exceeding 600 nm.

A person of ordinary skill in the art will understand, that any method described above or below and/or claimed and described as a sequence of steps is not restrictive in the sense of the order of steps.

### BRIEF DESCRIPTION OF THE DRAWINGS

Various objects, features and attendant advantages of the present invention will become fully appreciated when considered in conjunction with the accompanying drawings, in which like reference characters designate the same or similar parts throughout the several views, and wherein:

FIG. 1 shows an example of a conventional III-nitride semiconductor light emitting device that emits light in a red range;

FIG. 2 shows an example of a III-nitride semiconductor light emitting device according to the disclosure;

FIG. 3 shows examples of a semiconductor light emitting structure according to the disclosure;

FIG. 4 shows other examples of a semiconductor light emitting structure according to the disclosure;

FIG. 5 shows another example of a semiconductor light emitting structure according to the disclosure;

FIG. 6 shows an example of experiment results in the disclosure;

FIG. 7 shows another example of experiment results in the disclosure;

FIG. 8 shows another example of experiment results in the disclosure;

FIG. 9 shows another example of experiment results in the disclosure;

FIG. 10 shows another example of experiment results in the disclosure;

FIG. 11 illustrates bandgap energy of different semiconductor light emitting devices according to the disclosure;

FIGS. 12, 13 and 14 show further examples of experiment results in the disclosure;

FIG. 15 compares an active region of the quantum well structure with an active region of the superlattice structure;

FIG. 16 shows an example of experiment results of the semiconductor light emitting structure described in Table 7;

FIG. 17 illustrates various examples of semiconductor light emitting structures employing a superlattice structure;

FIG. 18 shows another example of a semiconductor light emitting structure according to the disclosure;

FIGS. 19, 20 and 21 illustrate a superlattice region and a lateral enhancement layer;

FIG. 22 shows another example of a semiconductor light emitting structure according to the disclosure;

FIGS. 23, 24, 25 and 26 show experiment results of the examples shown in FIGS. 18 to 22;

FIG. 27 illustrates another example of a semiconductor light-emitting device according to the present disclosure;

FIG. 28 illustrates another example of a semiconductor light-emitting device according to the present disclosure;

FIG. 29 illustrates another example of a semiconductor light-emitting device according to the present disclosure;

FIG. 30 illustrates another example of a semiconductor light-emitting device according to the present disclosure;

FIG. 31 illustrates another example of a semiconductor light-emitting device according to the present disclosure;

FIG. 32 illustrates an example of the opening pattern presented in FIG. 31;

FIG. 33 illustrates another example of the arrangement of openings in a growth mask according to the present disclosure;

FIGS. 34, 35 and 36 illustrate an example of a method for manufacturing a semiconductor light-emitting device according to the present disclosure;

FIGS. 37, 38, 39 and 40 illustrate another example of a method for manufacturing a semiconductor light-emitting device according to the present disclosure;

FIG. 41 illustrates an example of experimental results obtained using the method described in FIGS. 27 to 33;

FIG. 42 illustrates another example of experimental results obtained using the method described in FIGS. 27 to 33;

FIG. 43 summarizes the experimental results presented in FIGS. 41 and 42 as a graph;

FIG. 44 shows an example of photoluminescence (PL) experiment results in the disclosure;

FIG. 45 shows an example of field luminescence (EL) experiment results in the disclosure;

FIG. 46 shows an example of field luminescence (EL) experiment results with a laser being added according to the disclosure;

FIGS. 47, 48 and 49 illustrate the luminescence principle according to the disclosure;

FIG. 50 illustrates an example of a III-nitride semiconductor light-emitting device presented in Korean Patent Publication No. 2011-0037616;

FIG. 51 illustrates another example of a III-nitride semiconductor light-emitting device presented in Korean Patent Publication No. 2011-0037616;

FIG. 52 illustrates another example of a III-nitride semiconductor light-emitting structure or device according to the present disclosure;

FIG. 53 illustrates another example of a III-nitride semiconductor light-emitting structure or device according to the present disclosure;

FIG. 54 illustrates another example of a III-nitride semiconductor light-emitting structure or device according to the present disclosure;

FIG. 55 illustrates another example of a III-nitride semiconductor light-emitting structure or device according to the present disclosure;

FIG. 56 illustrates another example of a III-nitride semiconductor light-emitting structure or device according to the present disclosure;

FIG. 57 illustrates another example of a III-nitride semiconductor light-emitting structure or device according to the present disclosure;

FIG. 58 illustrates another example of a III-nitride semiconductor light-emitting structure or device according to the present disclosure;

FIG. 59 illustrates another example of a III-nitride semiconductor light-emitting structure or device according to the present disclosure;

FIG. 60 illustrates another example of a III-nitride semiconductor light-emitting structure or device according to the present disclosure;

FIGS. 61 and 62 illustrate experimental results demonstrating the actual implementation of the III-nitride semiconductor light-emitting structure or device described in FIGS. 52 to 60;

FIG. 63 illustrates additional experimental results demonstrating the actual implementation of the III-nitride semiconductor light-emitting structure or device described in FIGS. 52 to 60;

FIG. 64 illustrates an example of a method for measuring the wafer state of the III-nitride semiconductor light-emitting structure or device described in FIGS. 52 to 57;

FIG. 65 illustrates the actual process of the measurement described in FIG. 64;

FIGS. 66, 67 and 68 show other examples of measurement results in the disclosure;

FIG. 69 illustrates another example of a semiconductor light-emitting device according to the present disclosure;

FIG. 70 illustrates another example of a semiconductor light-emitting device according to the present disclosure;

FIG. 71 illustrates another example of a semiconductor light-emitting device according to the present disclosure.

### DETAILED DESCRIPTION OF THE PREFERRED EMBODIMENTS

The disclosure will now be described in detail with reference to the accompanying drawing(s).

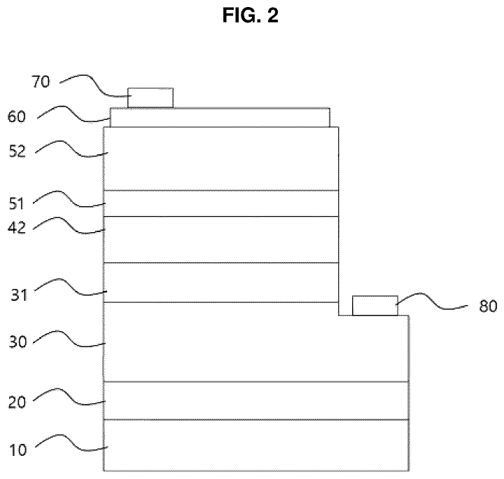

FIG. 2 shows an example of a III-nitride semiconductor light emitting device according to the disclosure, in which the semiconductor light emitting device includes a growth substrate 10, a buffer region 20, an n-side contact region 30, a superlattice region 31. a semiconductor light emitting structure or active region 42, an electron blocking layer 51 (EBL), a p-side contact region 52, a current spreading electrode 60, a first electrode 70, and a second electrode 80.

The growth substrate 10 may be a sapphire substrate, a Si 111 substrate or the like. In particular, a patterned C-face sapphire substrate (C-face PSS) may be used, and there is no particular limitation on the use of heterogeneous or homogeneous substrates.

The buffer region 20 may be made of un-doped GaN that is formed on the seed layer, and its growth conditions (based on MOVCD method) are as follows: a temperature of 950° C. to 1100° C., a thickness of 1 to 4 μm, a pressure of 100 to 400 mbar, and H₂ atmosphere.

The n-side contact region 30 may be made of Si-doped GaN, and its growth conditions are as follows: a temperature of 1000° C. to 1100° C., a thickness of 1 to 4 μm, a pressure of 100 to 400 mbar, and H₂ atmosphere.

The superlattice region 31 is a stack of InaGa₁₋ₐN/InbGa_{1-b}N (15 cycles of repetition of 0<a<1, 0≤b<1, a>b) superlattice structure that is formed under general growth conditions to improve current spreading. Optionally, Al can be added, and it can be doped with an n-type dopant (e.g., Si). Further, the composition may be slightly changed during the repetition process.

The electron blocking layer 51 may be made of Mg-doped AlGaN, and its growth conditions are as follows: a temperature of 900° C., a thickness of 10 to 40 nm, a pressure of 50 to 100 mbar, and H₂ atmosphere.

The p-side contact region 52 can also be made of Mg-doped GaN under normal growth conditions.

The current spreading electrode 60 may be made of TCO (Transparent Conductive Oxide) such as ITO, but it is not limited thereto.

The first electrode 70 and the second electrode 80 may be made of Cr/Ni/Au.

The structure used in the example of FIG. 2 is a very common structure conventionally used to make semiconductor light emitting devices that emit blue and green light using III-nitride semiconductors. Any structure suitable for III-nitride semiconductor light emitting devices that emit blue and green light can be used without any specific limitations. While a lateral chip is illustrated in this example, any other form such as a flip chip and vertical chip may also be used. For example, the light emitting device shown here has a chip form, but it can obviously have a wafer state as well.

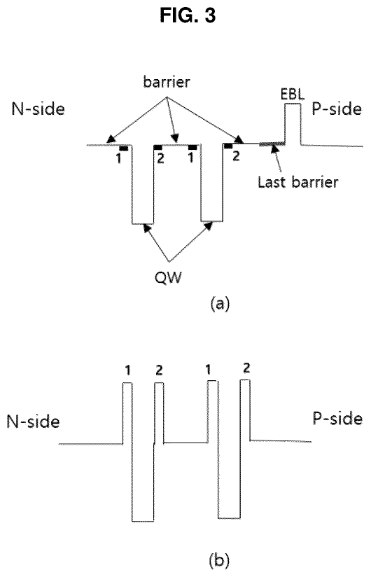

FIG. 3 shows examples of a semiconductor light emitting structure according to the disclosure. FIG. 3A shows a conventional III-nitride semiconductor light emitting structure that emits light in a green range, and FIG. 3B shows a III-nitride semiconductor light emitting structure according to the disclosure. For illustration purposes, two quantum wells are presented.

The semiconductor light emitting structure shown in FIG. 3A employs a quantum well (QW) made of In_{c}Ga_{1-c}N and a barrier made of Al_{d}GaₑIn_{1-d-e}N (0≤d≤1, 0≤e≤1; e.g., GaN). The content c of In significantly varies depending on the peak wavelength at which the semiconductor light emitting structure emits light. For example, in case of blue light emission, c can have a value of 0.1; in case of green light emission, c can have a value of 0.2. Examples of the barrier may include InGaN, AlGaN, AlGaInN, and the like, but GaN is typically used.

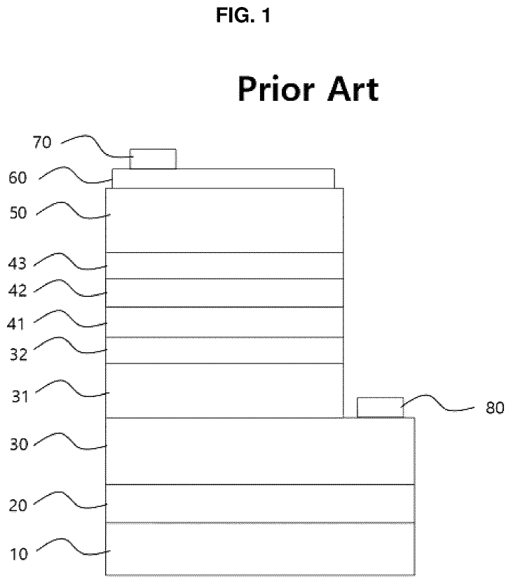

The semiconductor light emitting structure according to the disclosure is a combination of the semiconductor light emitting structure as shown in FIG. 3A, which has already been commercially available and stably implemented, with the barrier structure as shown in FIG. 3B, such that light of longer wavelengths can be emitted. Incorporating the semiconductor light emitting structure of the disclosure enables to overcome the issues in the In-rich InGaN active region of FIG. 1, as well as the issues in the operation of the semiconductor light emitting device thus manufactured.

TABLE 1

| | First (x), | First (x), | First (∘), | First (∘), |
|---|---|---|---|---|
| | Second (x) | Second (∘) | Second (x) | Second (∘) |
| Wavelength | 530 (Green) | 560 | 580 | 625 (Red) |
| (Wp, nm) | | | | |
| Optical power | Bright | Dim | Moderate | Moderate |
| (Qualitative | | | | |
| evaluation) | | | | |

As described in Table 1, (i) when neither the first layer 1 nor the second layer 2 according to the disclosure is not provided on either side of the quantum well, the device emits bright light with a wavelength Qh of 530 nm, (ii) when only the second layer 2 according to the disclosure is provided in the quantum well, the device emits dim light with a wavelength of 560 nm, (iii) when only the first layer 1 according to the disclosure is provided in the quantum well, the device emits light of moderate brightness with a wavelength of 580 nm, and (iv) when both the first layer 1 and the second layer 2 according to the disclosure are provided on both sides of the quantum well, the device emits light of moderate brightness with a wavelength of 625 nm.

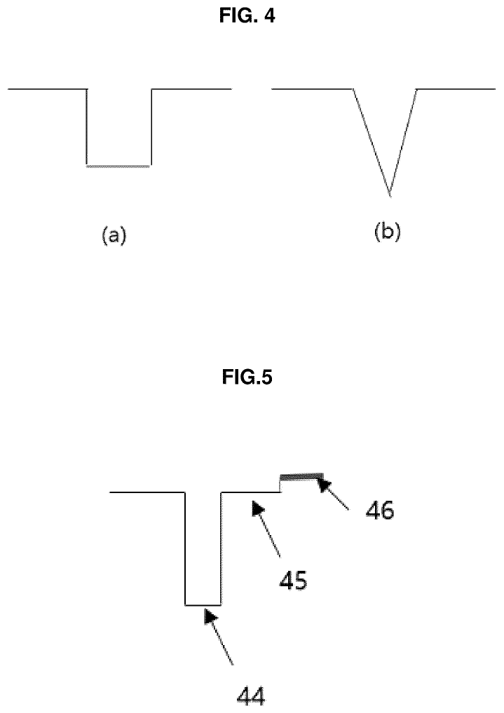

FIG. 4 shows other examples of a semiconductor light emitting structure according to the disclosure. FIG. 4A shows an example in which In is uniformly distributed during the formation of a quantum well. FIG. 4B shows an example in which the distribution of In is graded (that is, it is first decreased and then increased) during the formation of the quantum well. When the same total amount of In was provided to each quantum well, the structure in FIG. 4B exhibited brighter light.

FIG. 5 shows another example of a semiconductor light emitting structure according to the disclosure. It demonstrates that changing the material composition of the last barrier (the barrier closest to the p-side in the semiconductor light emitting structure) from GaN to another material (such as InGaN) having a lower bandgap energy than GaN can extend the emission wavelength of the semiconductor light emitting structure. For example, it was confirmed that if an In/(In+Ga) ratio is appropriately adjusted (e.g., 0.05 or 0.10; where the ratio indicates the molar ratio between MO sources (TEGa (TriEthyl Ga), TMIn (TriMethyl In), TMAl (TriMethyl Al) in the vapor phase during growth), a semiconductor light emitting structure that emits light with a wavelength of 625 nm is capable of emitting light with a wavelength of 635 nm.

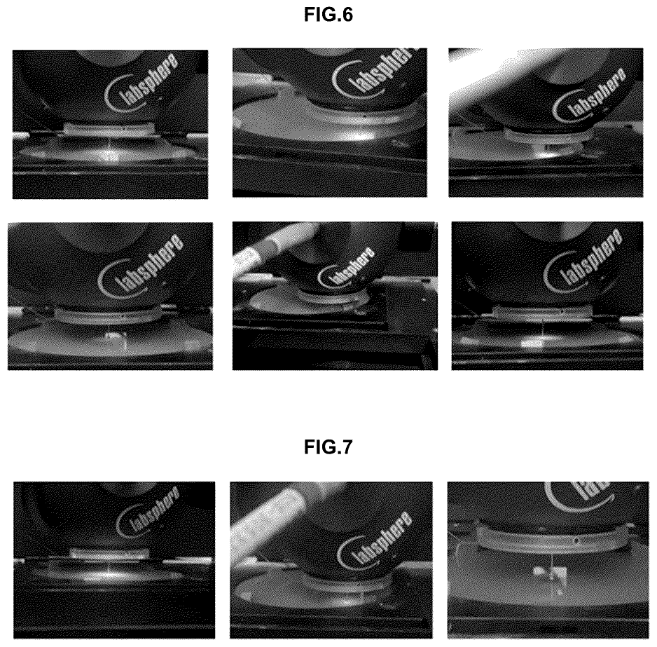

FIG. 6 shows an example of experiment results in the disclosure. The top left illustrates a case where both the first layer 1 and the second layer 2 are absent (green); the top middle illustrates a case where only the second layer 2 is present (yellow); the top right illustrates a case where only the first layer 1 is present (orange); the bottom left illustrates a case where both the first layer 1 and the second layer 2 are present (red); the bottom middle illustrates a case in FIG. 5 (redder or more intense red); and the bottom right illustrates a case where Al_{f}Ga_{1-f}N (the ratio of Al/(Al+Ga) is 0.95) is used (blue).

For the experiments, a GaN barrier (4 nm) and an In_{c}Ga_{1-c}N well layer (2.5 nm) with an In/(In+Ga) ratio of 0.56 were used. In particular, two quantum wells were used to form a base structure as follows: GaN barrier (4 nm)—In_{c}Ga_{1-c}N well layer (2.5 nm)—GaN barrier (4 nm)—In_{c}Ga_{1-c}N well layer (2.5 nm)—GaN barrier (8 nm). Although 1 to 4 quantum wells were tested due to limitations in the experiments, there were no significant variations in the optical properties. For the first layer 1 and the second layer 2, Al_{f}Ga_{1-f}N (2 nm) with an Al/(Al+Ga) ratio of 0.85 was used.

The well layers (quantum wells) were grown to a thickness of 2.5 nm at a temperature of 670° C. using TMGa and TMIn, and the barriers were grown to a thickness of 4 nm at a temperature of 770° C. using GaN. For the first layer 1 located first on the n-side, Al_{f}Ga_{1-f}N (2 nm) with an Al/(Al+Ga) ratio of 0.85 is grown using TMAl and TMGa under the same conditions as the first barrier immediately after the growth of the first barrier (located first on the n-side) (they together form the barrier). Once the first quantum well (the first well layer located on the n-side) is grown, the second layer 2 located on the n-side is grown to a thickness of 0.3 nm using TMGa and TMAl by raising the temperature for 50 seconds. Afterwards, the remaining 1.7 nm is grown under the same growth conditions as the barrier, and the GaN barrier is grown. The first layer 1 and the second layer 2 located on the p-side are also grown in the same manner. The semiconductor light emitting structure 42 provided with the first layer 1 as well as the second layer 2 has the structure of the last GaN (1.5 nm) in the superlattice region 31—GaN barrier (4 nm)—first Al_{f}Ga_{1-f}N (2 nm) layer 1—In_{c}Ga_{1-c}N well layer (2.5 nm)—second Al_{f}Ga_{1-f}N (2 nm) layer 2—GaN barrier (4 nm)—first Al_{f}Ga_{1-f}N (2 nm) layer 1—In_{c}Ga_{1-c}N well layer (2.5 nm)—second Al_{f}Ga_{1-f}N (2 nm) layer 2—GaN barrier (8 nm)—electron blocking layer 51. In the semiconductor light emitting structure shown in FIG. 5, the last barrier (adjacent to the electron blocking layer 51) can have the structure of In_{g}Ga_{1-g}N barrier (4 nm)—GaN barrier (4 nm).

As shown in FIG. 6, the emission wavelength can be shifted to a longer range by introducing the first layer 1 and/or the second layer 2 into a given semiconductor light emitting structure. However, as shown in the bottom right of FIG. 6, it is observed when the Al concentration in the first and second layers 1 and 2 is beyond a certain threshold, the wavelength shifts toward a shorter range compared to the original emission wavelength of the semiconductor light emitting structure.

Table 2 below summarizes examples of growth conditions for conventional superlattice regions 31. As described earlier, the composition in the disclosure is represented by the molar ratio between MO sources (TriEthyl Ga (TEGa), TriMethyl In (TMIn), and TriMethyl Al (TMAl).

TABLE 2

| | Growth | | |
|---|---|---|---|
| | temperature | Composition | Thickness |
| InₐGa₁₋ₐN | 720° C. | In/(In + Ga) = | 1.5 nm |
| (Superlattice region (31)) | | 0.55 | |
| In_{b}Ga_{1-b} N | 780° C. | b = 0 (GaN) | 1.5 nm |
| (Superlattice region (31)) | | | |

Here, the superlattice region 31 may be fully or partially doped. For example, only the barrier In_{b}Ga_{1-b}N (superlattice region 31) may be doped with Si at about 5×10¹⁸/cm³, or only the even-numbered barriers may be doped, or only the odd-numbered barriers may be doped.

Table 3 below summarizes examples of growth conditions for the conventional semiconductor light emitting structure or active region 42.

TABLE 3

| | Growth | | |
|---|---|---|---|
| | temperature | Composition | Thickness |
| Al_{d}GaₑIn_{1-d-e}N barrier | 770° C. | d = 0, e = 1 | 4 nm |
| (Semiconductor light | | (GaN) | |
| emitting structure (42)) | | | |
| In_{c}Ga_{1-c}N well layer | 670° C. | In/(In + Ga) = | 2.5 nm |
| (Semiconductor light | | 0.56 | |
| emitting structure (42)) | | | |
| Al_{d}GaₑIn_{1-d-e}N barrier | 770° C. | d = 0, e = 1 | 4 nm |
| (Semiconductor light | | (GaN) | |
| emitting structure (42)) | | | |
| In_{c}Ga_{1-c}N well layer | 670° C. | In/(In + Ga) = | 2.5 nm |
| (Semiconductor light | | 0.56 | |
| emitting structure (42)) | | | |
| Al_{d}GaₑIn_{1-d-e}N barrier | 770° C. | d = 0, e = 1 | 8 nm |
| (Semiconductor light | | (GaN) | |
| emitting structure (42)) | | | |

Table 4 below summarizes examples of growth conditions used for the semiconductor light emitting structure or active region 42 according to the disclosure.

TABLE 4

| | Growth | | |
|---|---|---|---|
| | temperature | Composition | Thickness |
| Al_{d}GaₑIn_{1-d-e}N barrier | 770° C. | d = 0, e = 1 | 4 nm |
| (Semiconductor light emitting | | (GaN) | |
| structure (42)) | | | |
| First Al_{f}Ga_{1-f}N layer (1) | 770° C. | Al/(Al + Ga) = | 2 nm |
| | | 0.85 | |
| In_{c}Ga_{1-c}N well layer | 670° C. | In/(In + Ga) = | 2.5 nm |
| (Semiconductor light emitting | | 0.56 | |
| structure (42)) | | | |
| Second Al_{f}Ga_{1-f}N layer (2) | 770° C. | Al/(Al + Ga) = | 2 nm |
| | | 0.85 | |
| Al_{d}GaₑIn_{1-d-e}N barrier | 770° C. | d = 0, e = 1 | 4 nm |
| (Semiconductor light emitting | | (GaN) | |
| structure (42)) | | | |
| First Al_{f}Ga_{1-f}N layer (1) | 770° C. | Al/(Al + Ga) = | 2 nm |
| | | 0.85 | |
| In_{c}Ga_{1-c}N well layer | 670° C. | In/(In + Ga) = | 2.5 nm |
| (Semiconductor light emitting | | 0.56 | |
| structure (42)) | | | |
| Second Al_{f}Ga_{1-f}N layer (2) | 770° C. | Al/(Al + Ga) = | 2 nm |
| | | 0.85 | |
| Al_{d}GaₑIn_{1-d-e}N barrier | 770° C. | d = 0, e = 1 | 8 nm |
| (Semiconductor light emitting | | (GaN) | |
| structure (42)) | | | |

Table 5 below summarizes examples of growth conditions used for the semiconductor light emitting structure or active region 42, as shown in FIG. 5.

TABLE 5

| | Growth | | |
|---|---|---|---|
| | temperature | Composition | Thickness |
| Al_{d}GaₑIn_{1-d-e}N barrier | 770° C. | d = 0, e = 1 | 4 nm |
| (Semiconductor light emitting | | (GaN) | |
| structure (42)) | | | |
| First Al_{f}Ga_{1-f}N layer (1) | 770° C. | Al/(Al + Ga) = | 2 nm |
| | | 0.85 | |
| In_{c}Ga_{1-c}N well layer | 670° C. | In/(In + Ga) = | 2.5 nm |
| (Semiconductor light emitting | | 0.56 | |
| structure (42)) | | | |
| Second Al_{f}Ga_{1-f}N layer (2) | 770° C. | Al/(Al + Ga) = | 2 nm |
| | | 0.85 | |
| Al_{d}GaₑIn_{1-d-e}N barrier | 770° C. | d = 0, e = 1 | 4 nm |
| (Semiconductor light emitting | | (GaN) | |
| structure (42)) | | | |
| First Al_{f}Ga_{1-f}N layer (1) | 770° C. | Al/(Al + Ga) = | 2 nm |
| | | 0.85 | |
| In_{c}Ga_{1-c}N well layer | 670° C. | In/(In + Ga) = | 2.5 nm |
| (Semiconductor light emitting | | 0.56 | |
| structure (42)) | | | |
| Second Al_{f}Ga_{1-f}N layer (2) | 770° C. | Al/(Al + Ga) = | 2 nm |
| | | 0.85 | |
| In_{g}Ga_{1-g}N well layer | 770° C. | In/(In + Ga) = | 4 nm |
| (Semiconductor light emitting | | 0.01 | |
| structure (42)) | | | |
| Al_{d}GaₑIn_{1-d-e}N barrier | 770° C. | d = 0, e = 1 | 4 nm |
| (Semiconductor light emitting | | (GaN) | |
| structure (42)) | | | |

FIG. 7 shows another example of experiment results in the disclosure, related to changes in the emission wavelength based on the Al content in the semiconductor light emitting structure. The left illustrates a case where if the ratio of Al/(Al+Ga) is 0.25, yellow emission occurs; the middle illustrates a case where if the ratio of Al/(Al+Ga) is 0.75, red emission occurs; and the right illustrates a case where if the ratio of Al/(Al+Ga) is 0.95, blue emission occurs. With the semiconductor light emitting structure used in the experiment of FIG. 6, a significant change in the wavelength occurs when the Al content exceeds 20%, but the wavelength gets shorter again when the Al content exceeds 90%.

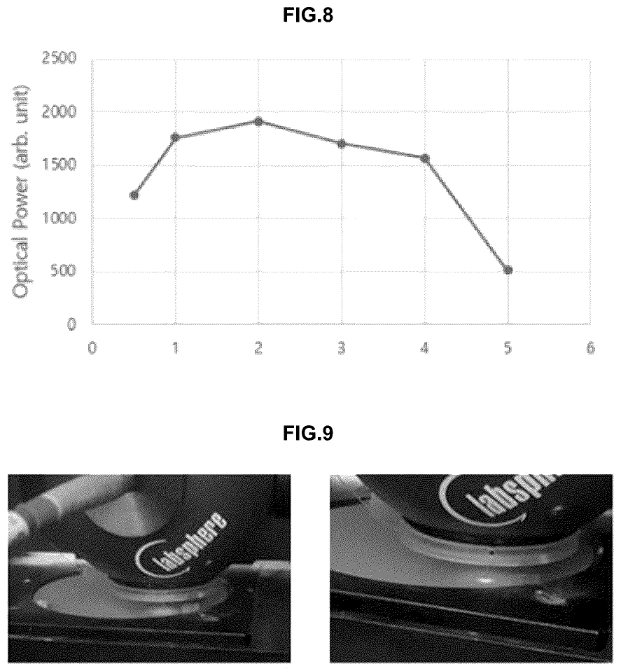

FIG. 8 shows another example of experiment results in the disclosure, related to variations in optical power based on a change in the thickness of the first layer 1 and the second layer 2. With the semiconductor light emitting structure shown in FIG. 6, the maximum intensity is observed at approximately 2 nm, but it sharply drops as the thickness reaches 5 nm. A desirable range for the thickness is therefore 0.5-4 nm.

FIG. 9 shows another example of experiment results in the disclosure, comparing the results of using the semiconductor light emitting structure in FIG. 4A (on the left) with the results of using the semiconductor light emitting structure in FIG. 4B (on the right). As can be seen, the example on the right shows brighter and more intense red emission.

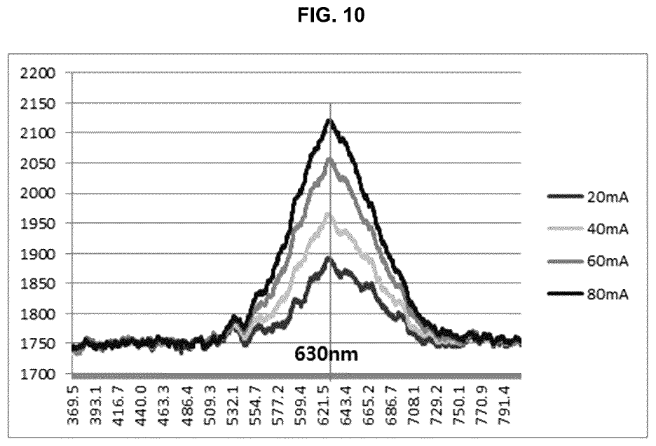

FIG. 10 shows another example of experiment results in the disclosure, related to the degree of wavelength shift with changes in current. As compared with the conventional In-rich InGaN red LED (which shows a drastic shift towards shorter wavelengths with increased current), the wavelength shift is much less pronounced in this example.

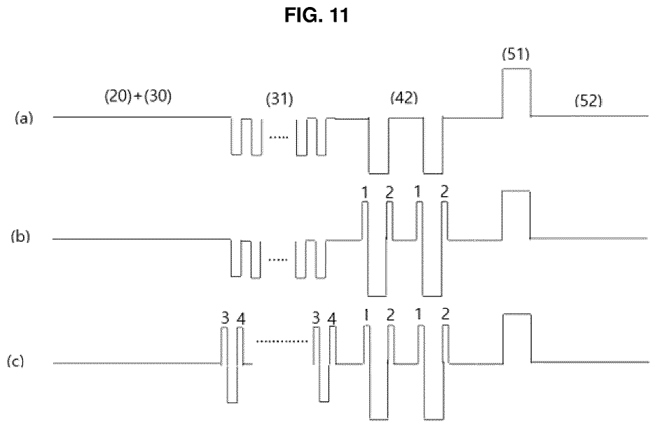

FIG. 11 illustrates bandgap energy of different semiconductor light emitting devices. FIG. 11A is obtained from a conventional semiconductor light emitting device, FIG. 11B is obtained from the semiconductor light emitting device shown in FIG. 2, and FIG. 11C is obtained from a semiconductor light emitting device which incorporates the barrier form of the semiconductor light emitting structure 42 into the superlattice region 31 in the structure shown in FIG. 11B.

Table 6 below summarizes examples of growth conditions used for the semiconductor light emitting device shown in FIG. 11C.

TABLE 6

| | Growth | | |
|---|---|---|---|
| | temperature | Composition | Thickness |
| Third Al_{g}Ga_{1-g}N layer (3) | 780° C. | Al/(Al + Ga) = | 0.8 nm |
| | | 0.50 | |
| InₐGa₁₋ₐN well layer | 720° C. | In/(In + Ga) = | 1.5 nm |
| (Superlattice region (31)) | | 0.55 | |
| Fourth Al_{g}Ga_{1-g}N layer (4) | 780° C. | Al/(Al + Ga) = | 0.8 nm |
| | | 0.50 | |
| In_{b}Ga_{1-b}N well layer | 780° C. | b = 0 (GaN) | 1.5 nm |
| (Superlattice region (31)) | | | |
| . | . | . | . |
| . | . | . | . |
| . | . | . | . |
| <<15 cycles>> | | | |
| . | . | . | . |
| . | . | . | . |
| . | . | . | . |
| Third Al_{g}Ga_{1-g}N layer (3) | 780° C. | Al/(Al + Ga) = | 0.8 nm |
| | | 0.50 | |
| InₐGa₁₋ₐN well layer | 720° C. | In/(In + Ga) = | 1.5 nm |
| (Superlattice region (31)) | | 0.55 | |
| Fourth Al_{g}Ga_{1-g}N layer (4) | 780° C. | Al/(Al + Ga) = | 0.8 nm |
| | | 0.50 | |
| In_{b}Ga_{1-b}N well layer | 780° C. | b = 0 (GaN) | 1.5 nm |
| (Superlattice region (31)) | | | |
| Al_{d}GaₑIn_{1-d-e}N barrier | 770° C. | d = 0, e = 1 | 4 nm |
| (Semiconductor light | | (GaN) | |
| emitting structure (42)) | | | |
| First Al_{f}Ga_{1-f}N layer (1) | 770° C. | Al/(Al + Ga) = | 2 nm |
| | | 0.85 | |
| In_{c}Ga_{1-c}N well layer | 670° C. | In/(In + Ga) = | 2.5 nm |
| (Semiconductor light | | 0.56 | |
| emitting structure (42)) | | | |
| Second Al_{f}Ga_{1-f}N layer (2) | 770° C. | Al/(Al + Ga) = | 2 nm |
| | | 0.85 | |
| Al_{d}GaₑIn_{1-d-e}N barrier | 770° C. | d = 0, e = 1 | 4 nm |
| (Semiconductor light | | (GaN) | |
| emitting structure (42)) | | | |
| First Al_{f}Ga_{1-f}N layer (1) | 770° C. | Al/(Al + Ga) = | 2 nm |
| | | 0.85 | |
| In_{c}Ga_{1-c}N well layer | 670° C. | In/(In + Ga) = | 2.5 nm |
| (Semiconductor light | | 0.56 | |
| emitting structure (42)) | | | |
| Second Al_{f}Ga_{1-f}N layer (2) | 770° C. | Al/(Al + Ga) = | 2 nm |
| | | 0.85 | |
| Al_{d}GaₑIn_{1-d-e}N barrier | 770° C. | d = 0, e = 1 | 8 nm |
| (Semiconductor light | | (GaN) | |
| emitting structure (42)) | | | |

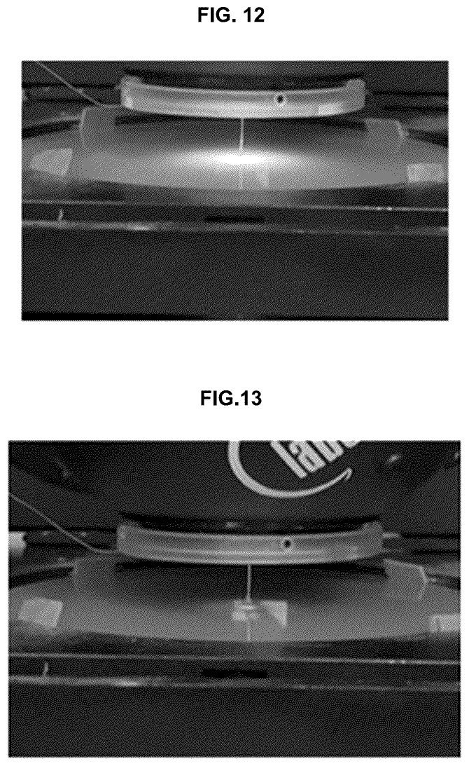

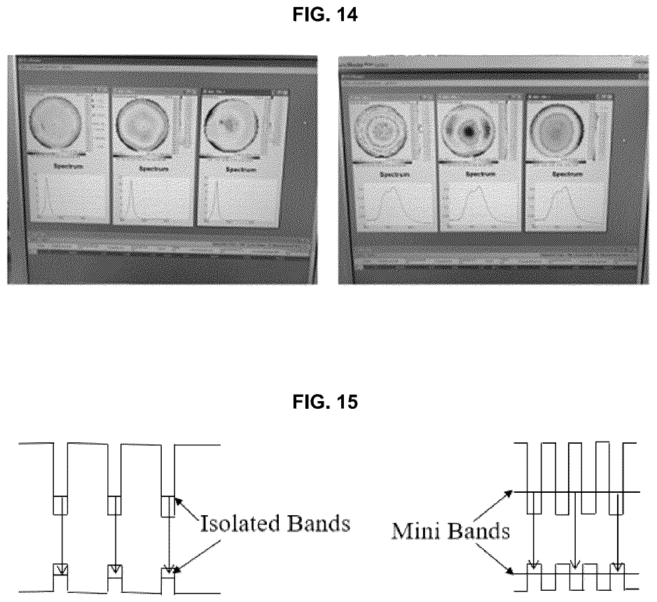

FIGS. 12 to 14 show further examples of experiment results in the disclosure. In particular, FIG. 12 shows experiment results for the semiconductor light emitting device of FIG. 11C, for which all growth conditions are kept the same as in FIG. 11B except that the quantum well region 31 is absent. Similar to the example on the right side in FIG. 7, a shift towards shorter wavelengths is observed. This suggests that the incorporation of the third and fourth layers 3 and 4, into the superlattice region 31 (i.e. the superlattice region 31 as shown in FIG. 11C) increases the amount of In injected into the well layers of the semiconductor light emitting structure 42. FIG. 13 shows that when the ratio of Al/(Al+Ga) in the first and second layers 1 and 2 is lowered from 0.85 to 0.45, red light emission (635 nm) is at least twice as that of the semiconductor light emitting device of FIG. 11B. FIG. 14 shows PL measurement results of the superlattice region 31 with or without the third and fourth layers 3 and 4. The results confirm that in the presence of the third and fourth layers 3 and 4, the PL peak makes a significant shift in longer wavelength ranges, from 445 nm to 535 nm.

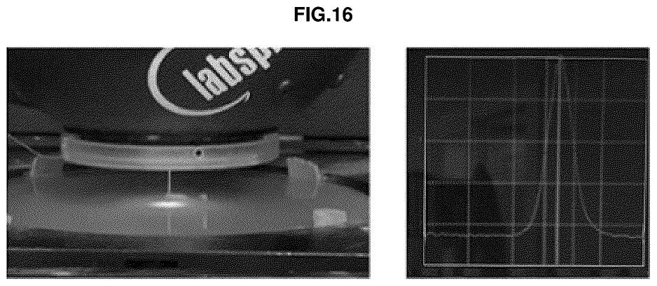

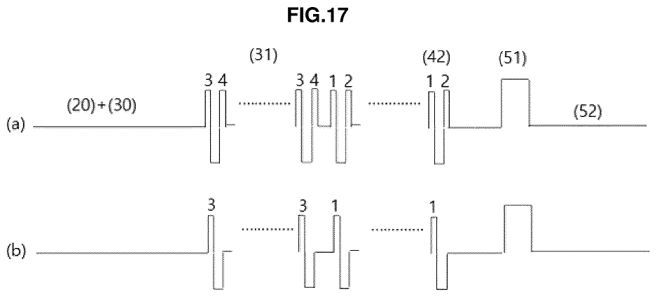

Table 7 below summarizes examples of growth conditions for the semiconductor light emitting device of FIG. 11C, in which the active region 42 of the quantum well structure is modified to a semiconductor light emitting region or active region 42 of the superlattice structure similar to the superlattice region 31. Referring to FIG. 15 which compares the active region of the quantum well structure (the left) with the active region of the superlattice structure (the right), each quantum well in the active region of the quantum well structure forms isolated bands due to a thick barrier and emits light independently through electron-hole recombination, while each well in the active region of the superlattice structure (that is, the barrier becomes sufficiently thin) is not isolated and forms minibands to emit light through miniband transition. Although the active region of the superlattice structure is not commonly used in III-nitride semiconductor light emitting devices, it was found to be very effective when applied to the semiconductor light emitting structure of the disclosure (see FIG. 16). That is to say, the active region 42 is constructed to be the same as the superlattice region 31, with some specific conditions as follows: 8 cycles are used; no doping is performed; the growth temperature for the well layers is set at 700° C., while the growth temperature for the other layers is set at 780° C., the thickness of the first and second layers 1 and 2 is set to 0.8 nm; the thickness of Al_{d}Gaₑ In_{1-de}N barrier (d=0, e=1 (GaN)) is set to 1.5 nm; the ratio of the well layer In/(In+Ga) is set to 0.55; the ratio of Al/(Al+Ga) in the first layer 1 and the second layer 2 is set to 0.50; and the thickness of the well layer is set to 1.5 nm.

TABLE 7

| | Growth | | |
|---|---|---|---|
| | temperature | Composition | Thickness |
| Third Al_{g}Ga_{1-g}N layer (3) | 780° C. | Al/(Al + Ga) = | 0.8 nm |
| | | 0.50 | |
| InₐGa₁₋ₐN well layer | 720° C. | In/(In + Ga) = | 1.5 nm |
| (Superlattice region (31)) | | 0.55 | |
| Fourth Al_{g}Ga_{1-g}N layer (4) | 780° C. | Al/(Al + Ga) = | 0.8 nm |
| | | 0.50 | |
| In_{b}Ga_{1-b}N well layer | 780° C. | b = 0 (GaN) | 1.5 nm |
| (Superlattice region (31)) | | | |
| . | . | . | . |
| . | . | . | . |
| . | . | . | . |
| <<15 cycles>> | | | |
| . | . | . | . |
| . | . | . | . |
| . | . | . | . |
| Third Al_{g}Ga_{1-g}N layer (3) | 780° C. | Al/(Al + Ga) = | 0.8 nm |
| | | 0.50 | |
| InₐGa₁₋ₐN well layer | 720° C. | In/(In + Ga) = | 1.5 nm |
| (Superlattice region (31)) | | 0.55 | |
| Fourth Al_{g}Ga_{1-g}N layer (4) | 780° C. | Al/(Al + Ga) = | 0.8 nm |
| | | 0.50 | |
| In_{b}Ga_{1-b}N well layer | 780° C. | b = 0 (GaN) | 1.5 nm |
| (Superlattice region (31)) | | | |
| Al_{d}GaₑIn_{1-d-e}N barrier | 780° C. | d = 0, e = 1 | 4 nm |
| (Semiconductor light emitting | | (GaN) | |
| structure (42)) | | | |
| First Al_{f}Ga_{1-f}N layer (1) | 780° C. | Al/(Al + Ga) = | 0.8 nm |
| | | 0.50 | |
| In_{c}Ga_{1-c}N well layer | 700° C. | In/(In + Ga) = | 1.5 nm |
| (Semiconductor light emitting | | 0.55 | |
| structure (42)) | | | |
| Second Al_{f}Ga_{1-f}N layer (2) | 780° C. | Al/(Al + Ga) = | 0.8 nm |
| | | 0.50 | |
| Al_{d}GaₑIn_{1-d-e}N barrier | 780° C. | d = 0, e = 1 | 1.5 nm |
| (Semiconductor light emitting | | (GaN) | |
| structure (42)) | | | |
| . | . | . | . |
| . | . | . | . |
| . | . | . | . |
| <<8 cycles>> | | | |
| . | . | . | . |
| . | . | . | . |
| . | . | . | . |
| First Al_{f}Ga_{1-f}N layer (1) | 780° C. | Al/(Al + Ga) = | 0.8 nm |
| | | 0.50 | |
| In_{c}Ga_{1-c}N well layer | 700° C. | In/(In + Ga) = | 1.5 nm |
| (Semiconductor light emitting | | 0.55 | |
| structure (42)) | | | |
| Second Al_{f}Ga_{1-f}N layer (2) | 780° C. | Al/(Al + Ga) = | 0.8 nm |
| | | 0.50 | |
| Al_{d}GaₑIn_{1-d-e}N barrier | 780° C. | d = 0, e = 1 | 8 nm |
| (Semiconductor light emitting | | (GaN) | |
| structure (42)) | | | |

FIG. 16 shows an example of experiment results for the semiconductor light emitting structure described in Table 7. It confirms a 7-fold increase in output compared with the example described in Table 6.

FIG. 17 illustrates various examples of semiconductor light emitting structures employing a superlattice structure. In particular, FIG. 17A illustrates the bandgap energy of the semiconductor light emitting device described in Table 7, and FIG. 17B illustrates the semiconductor light emitting device from which the layers (i.e. the second layer 2 and the fourth layer 4) are removed from the p-side of the semiconductor light emitting structure 42 and the superlattice region 31. The semiconductor light emitting device illustrated in FIG. 17B demonstrated similar experiment results to those of the semiconductor light emitting device illustrated in FIG. 17A, under the same growth conditions but a modified ratio of Al/(Al+Ga) in the first layer 1 from 0.50 to 0.65.

In the semiconductor light emitting device illustrated in FIG. 17B, if the thickness of AlₐGaₑ In_{1-d-e}N barrier (d=0, e=1 (GaN)) of the semiconductor light emitting structure 42 is reduced from 1.5 nm to 1 nm, an emission wavelength shifts from 630 nm to 640 nm, moving towards a longer wavelength.

In the semiconductor light emitting device illustrated in FIG. 17B, if the repetition cycle of the semiconductor light emitting structure 42 is modified from 8 cycles to 16 cycles, an emission wavelength shortens to 625 nm, while the power intensity stayed relatively similar.

In the semiconductor light emitting device illustrated in FIG. 17B, if the thickness of Al_{d}Gaₑ In_{1-d-e}N barrier (d=0, e=1 (GaN)) of the semiconductor light emitting structure 42 is reduced from 1.5 nm to 0.75 nm, the thickness of the first layer 1 is reduced from 0.8 nm to 0.4 nm, and the thickness of the well layer is reduced from 1.5 nm to 0.75 nm, the wavelength shortens from 630 nm to 600 nm and the optical power is lowered by at least 50%.

In the semiconductor light emitting device illustrated in FIG. 17B, if the thickness of Al_{d}Gaₑ In_{1-d-e}N barrier (d=0, e=1 (GaN)) of the semiconductor light emitting structure 42 is reduced from 1.5 nm to 1.0 nm, the thickness of the first layer 1 is remained at 0.8 nm, and the thickness of the well layer is increased from 1.5 nm to 2.0 nm, the wavelength significantly increases from 630 nm to 680 nm, while the optical power is lowered by at least 50%. With these conditions, raising the growth temperature to a higher level may change the emission wavelength back to 630 nm, while the optical power is increased by 20% as compared with the semiconductor light emitting device illustrated in FIG. 17B.

Various changes can be made, which may include adding dopants to each layer of the superlattice region 31 and the semiconductor light emitting structure 42, adding Al, In or Ga, or slightly modifying the composition and growth conditions during the repetition process.

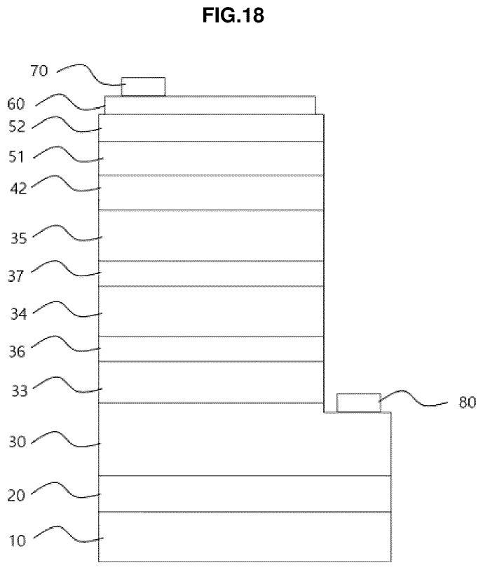

FIG. 18 shows another example of a semiconductor light emitting structure according to the disclosure. Unlike the semiconductor light emitting structure shown in FIG. 2, this example includes a plurality of superlattice regions 33, 34, 35 and uses an active region 42 with the superlattice structure is used. A lateral enhancement layer 36 is provided between the superlattice region 33 and the superlattice region 34, and a lateral enhancement layer 37 is provided between the between the superlattice region 34 and the superlattice region 35.

The superlattice regions 33, 34, 35 can be composed of sequentially repeated layers of AlGaN—InGaN—GaN, GaN—InGaN—AlGaN, GaN—AlGaN—InGaN—AlGaN, or AlGaN—InGaN. It is sufficient that the superlattice region 33, 34, 35 has therein an interface of AlGaN—InGaN, which may lead to the presence of AlInGaN either by diffusion or by intentional formation. In conventional III-nitride semiconductor light emitting devices, superlattice regions are primarily used to reduce the energy band gap difference between the n-type contact region 30 (e.g., GaN) and the active region containing InGaN. However, in this disclosure, the superlattice regions 33, 34, 35 are used not only to reduce the energy band gap as aforementioned, but also to increase the amount of In incorporated into the active region 42. Due to the large lattice constant difference between GaN and InGaN, it is difficult to incorporate In into the active region, but by increasing the In content through the superlattice regions 33, 34, 35, more In can be effectively incorporated into the active region 42. In particular, as In is introduced into the superlattice region 33, the superlattice region 34 would contain more In even under the same growth conditions, and the same applies to the superlattice region 35.

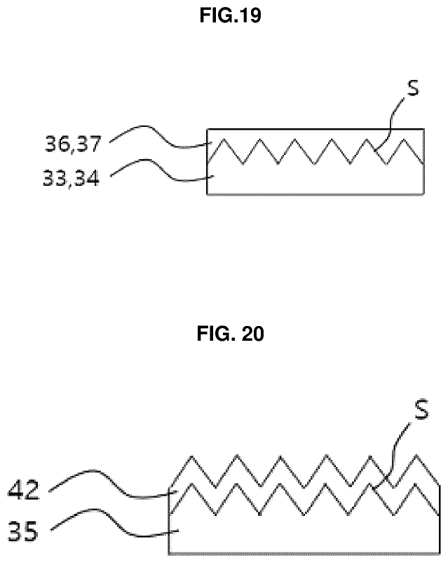

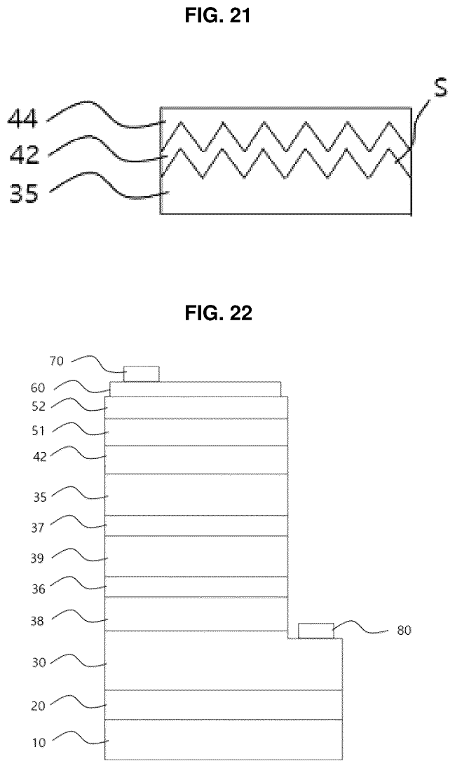

The superlattice regions 33, 34, 35 formed as described above would not have a flat surface due to the AlGaN—InGaN interface, but rather, they have a rough surface S as shown in FIGS. 19 to 21. As continuous accumulation of the rough surface S of the superlattice region 33 can increase the crystal defects of the device, a lateral enhancement layer 36 is introduced to make the surface flat, the superlattice region 34 is also introduced to facilitate the incorporation of In into the active region 42, and the lateral enhancement layer 37 is further introduced to eliminate the crystal defects. While there is no upper limit, at least one superlattice region 33, 34, 35 may be provided. More preferably, though, as shown in FIG. 21, no lateral enhancement layer is introduced between the active region 42 and the nearest superlattice region 35. The rough surface S is comprised of a semi-polar facet. For example, when the growth substrate 10 is a C-plane sapphire substrate, a flat, III-nitride semiconductor grown thereon has a polar facet which grows along the c-axis, but a three dimensional surface which forms the rough surface S comprises a semi-polar faucet. A polar facet makes In injection easier, but it has a high piezoelectric constant (that is, when the piezoelectric constant is high, the wavelength can shift significantly toward shorter wavelength ranges as the current density increases). Meanwhile, a non-polar facet has zero piezoelectric constant is 0 but it makes In injection difficult. Therefore, this disclosure has grown the active region 42 on a rough surface S which is a semi-polar facet, facilitating In injection with an appropriate piezoelectric constant. As shown in FIG. 21, it is possible to grow the last barrier 44 of the active region 42 flat or in the shape of the rough surface S, by adjusting the growth conditions.

Table 8 below summarizes examples of growth conditions for the semiconductor light emitting structure of FIG. 18.

TABLE 8

| | Growth | | |
|---|---|---|---|
| | temperature | Composition | Thickness |
| GaN | 830° C. | | 1.5 nm |
| (Superlattice region (33)) | | | |
| InₓGa₁₋ₓN | 730° C. | x = 0.1 | 1.5 nm |
| (Superlattice region (33)) | | | |
| Al_{y}Ga_{1-y}N | 780° C. | y = 0.5 | 0.5 nm |
| (Superlattice region (33)) | | | |
| . | . | . | . |
| . | . | . | . |
| . | . | . | . |
| <<10 cycles>> | | | |
| . | . | . | . |
| . | . | . | . |
| . | . | . | . |
| GaN | 830° C. | | 100 |
| (Lateral enhancement layer | | | |
| (36)) | | | |
| GaN | 830° C. | | 1.5 |
| (Superlattice region (34)) | | | |
| InₓGa₁₋ₓN | 730° C. | x = 0.1 | 1.5 |
| (Superlattice region (34)) | | | |
| Al_{y}Ga_{1-y}N | 780° C. | y = 0.5 | 0.5 |
| (Superlattice region (34)) | | | |
| . | . | . | . |
| . | . | . | . |
| . | . | . | . |
| <<10 cycles>> | | | |
| . | . | . | . |
| . | . | . | . |
| . | . | . | . |
| GaN | 830° C. | | 100 |
| (Lateral enhancement layer | | | |
| (37)) | | | |
| Al_{y}Ga_{1-y}N | 780° C. | y = 0.5 | 0.5 |
| (Superlattice region (35)) | | | |
| InₓGa₁₋ₓN | 730° C. | x = 0.1 | 1.5 |
| (Superlattice region (35)) | | | |
| GaN | 830° C. | | 1.5 |
| (Superlattice region (35)) | | | |
| . | . | . | . |
| . | . | . | . |
| . | . | . | . |
| <<10 cycles>> | | | |
| . | . | . | . |
| . | . | . | . |
| . | . | . | . |
| InₓGa₁₋ₓN | 710° C. | x = 0.35 | 2.2 |
| (Active region (42)) | | | |
| InₓGa₁₋ₓN | 760° C. | x = 0.05 | 0.4 |
| (Active region (42)) | | | |
| Al_{y}Ga_{1-y}N | 760° C. | y = 0.1 | 0.8 |
| (Active region (42)) | | | |
| InₓGa₁₋ₓN | 760° C. | x = 0.05 | 0.4 |
| (Active region (42)) | | | |
| . | | | |
| . | | | |
| . | | | |
| <<3 cycles>> | | | |
| . | | | |
| . | | | |
| . | | | |
| Al_{y}Ga_{1-y}N | 760° C. | y = 0.05 | 6 |
| (Last barrier (44)) | | | |
| GaN | 760° C. | | 6 |
| (Last barrier (44)) | | | |
| InₓGa₁₋ₓN | 760° C. | x = 0.05 | 6 |
| (Last barrier (44)) | | | |
| Al_{y}Ga_{1-x-y}InₓN | 820° C. | X = 0.1, | 20 |
| Electron blocking layer (52)) | | y = 0.2 | |
| p-GaN | 900° C. | | 200 |
| (P-side contact region (52)) | | | |

The thickness of the lateral enhancement layers 36, 37 should be sufficient to cover the rough surface S, with no upper limit. However, if they become too thick (e.g., 500 nm), the thick GaN layer will be positioned before the active layer 42, which may significantly degrade the functionality of the superlattice regions 33, 34.

Unlike in the previous examples, the composition of In, Al, and Ga used here were based on predicted values in the solid state after the growth was completed. It should be noted that even with the same composition InxGa1-xN (x=0.1), the actual In content may increase as the growth progresses, and more In may need to be incorporated as the thickness of InGaN increases and as the growth progresses.

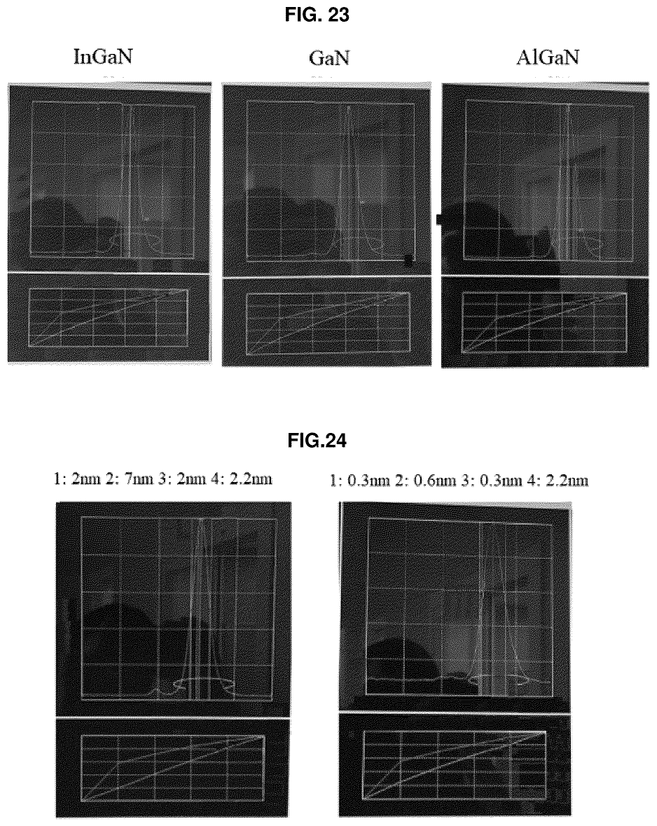

The last barrier 44 was tested with Al_{y}Ga_{1-y}N 44 (y=0.05), GaN 44, and InₓGa₁₋ₓN 44 (x=0.05), and Al_{y}Ga_{1-y}N 44 (y=0.05) showed the best light output. In conventional LED devices, adding Al to the last barrier (44) results in a shift toward shorter wavelengths, while adding In results in a shift toward longer wavelengths. In the device presented in this example, however, adding Al resulted in a shift toward longer wavelengths, and adding In resulted in a shift toward shorter wavelengths. It was found that adjusting the Al and In content enables to achieve a desired red light wavelength. Here, behavior opposite to conventional understanding has been applied, which is presumed to be attributed to strain effects. In the active region 42 presented in Table 8, it turned out that the last In_{0.05}Ga_{0.95}N (0.4 nm)—Al_{0.1}Ga_{0.9}N (0.8 nm)—In_{0.05}Ga_{0.95}N (0.4 nm) in the three cycles can be omitted and Al_{0.05}Ga_{0.95}N (last barrier 44 (6 nm), GaN (last barrier 44 (6 nm), or InₓGa₁₋ₓN (last barrier 44 (6 nm) can be formed instead. In particular, the last barrier 44 mainly comprised of Al_{0.05}Ga_{0.95}N (6 nm) was more effective than the last barrier 44 comprised of In_{0.05}Ga_{0.95}N (0.4 nm)—Al_{0.1}Ga_{0.9}N (0.8 nm)—In_{0.05}Ga_{0.95}N (0.4 nm)—Al_{0.05}Ga_{0.95}N (6 nm). Further, the last barrier 44 comprised of In_{0.05}Ga_{0.95}N (0.4 nm)—Al_{0.1}Ga_{0.9}N (0.8 nm)—In_{0.05}Ga_{0.95}N (0.4 nm)—In_{0.05}Ga_{0.95}N (6 nm) was more effective than the last barrier 44 mainly comprised of In_{0.05}Ga_{0.95}N (6 nm). In addition, the last barrier 44 using In_{0.05}Ga_{0.95}N (6 nm) was more effective than using GaN (6 nm) (see FIG. 23).

The thickness (2.2 nm) of InₓGa₁₋ₓN (active region 42 (x=0.35), which is the region corresponding to the well layer In the active region 42 (in the example shown, the active region 42 has a superlattice structure and forms a miniband, but for convenience of description, the expressions ‘well layer’ and ‘barrier layer’ used in the quantum well structure will be used as they are.) is greater than the thickness (1.6 nm=0.4 nm+0.8 nm+0.4 nm) of InₓGa₁₋ₓN (active region 42 (x=0.05)—Al_{y}Ga_{1-y}N (active region 42 (y=0.1)—InₓGa₁₋ₓN (active region 42 (x=0.05), which is the region corresponding to the barrier layer. It was also confirmed that, in the active region 42, the thinner the barrier layer, the thicker the well layer and the more the wavelength shifts toward longer wavelengths (see FIG. 24).

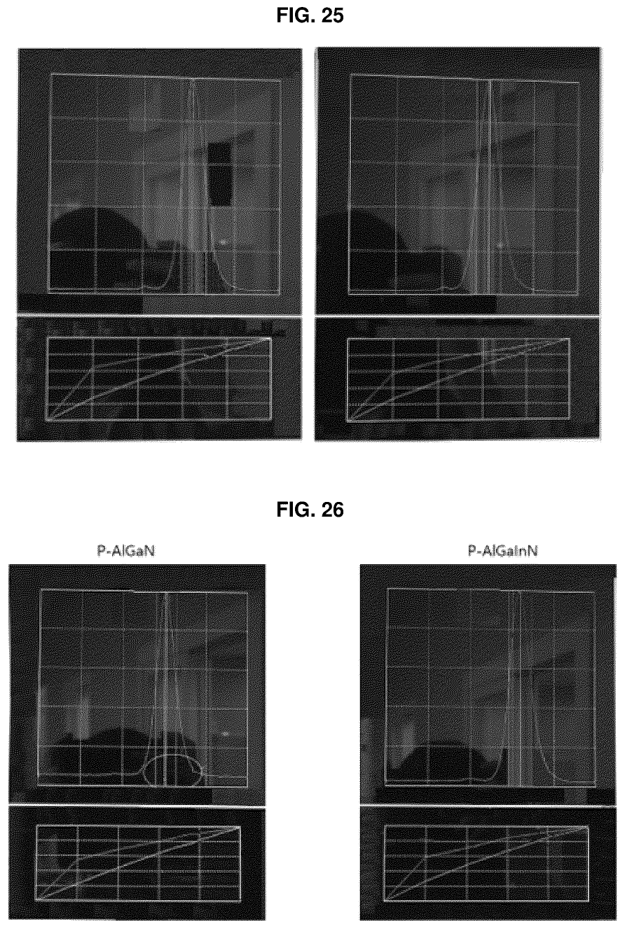

Additionally, as shown, the efficiency was increased by using InGaN—AlGaN—InGaN, instead of a single GaN, as a barrier (layer) (see FIG. 25).

Following the growth of the last barrier 44, the electron blocking layer 51 was grown with AlInGaN, instead of AlGaN, which resulted in a 10% increase in efficiency while shifting toward longer wavelengths (see FIG. 26).

FIG. 22 shows another example of a semiconductor light emitting structure according to the disclosure, which differs from the semiconductor light emitting device shown in FIG. 18 in that the superlattice regions 33, 34 are replaced with strain control regions 38, 39. In general, a superlattice structure is comprised of two or more layers with different band gaps grown alternately, each having a thickness of a few nanometers, forming a miniband due to tunneling.

Table 9 below summarizes examples of growth conditions for the semiconductor light emitting structure of FIG. 22.

TABLE 9

| | Growth | | |
|---|---|---|---|
| | temperature | Composition | Thickness |
| GaN | 870° C. | | 1.5 nm |
| (Superlattice region (38)) | | | |
| InₓGa₁₋ₓN | 770° C. | x = 0.05 | 30 nm |
| (Superlattice region (38)) | | | |
| Al_{y}Ga_{1-y}N | 870° C. | y = 0.2 | 5 nm |
| (Superlattice region (38)) | | | |
| . | . | . | . |
| . | . | . | . |
| . | . | . | . |
| <<10 cycles>> | | | |
| . | . | . | . |
| . | . | . | . |
| . | . | . | . |
| GaN | 1000° C. | | 45 |
| (Lateral enhancement layer | | | |
| (36)) | | | |
| GaN | 870° C. | | 15 |
| (Superlattice region (39)) | | | |
| InₓGa₁₋ₓN | 770° C. | x = 0.05 | 30 |
| (Superlattice region (39)) | | | |
| Al_{y}Ga_{1-y}N | 870° C. | y = 0.2 | 5 |
| (Superlattice region (39)) | | | |
| . | . | . | . |
| . | . | . | . |
| . | . | . | . |
| <<10 cycles>> | | | |
| . | . | . | . |
| . | . | . | . |
| . | . | . | . |
| GaN | 1000° C. | | 45 |
| (Lateral enhancement layer | | | |
| (37)) | | | |
| Al_{y}Ga_{1-y}N | 780° C. | y = 0.5 | 0.5 |
| (Superlattice region (35)) | | | |
| InₓGa₁₋ₓN | 730° C. | x = 0.1 | 1.5 |
| (Superlattice region (35)) | | | |
| GaN | 830° C. | | 1.5 |
| (Superlattice region (35)) | | | |
| . | . | . | . |
| . | . | . | . |
| . | . | . | . |
| <<10 cycles>> | | | |
| . | . | . | . |
| . | . | . | . |
| . | . | . | . |
| InₓGa₁₋ₓN | 710° C. | x = 0.35 | 2.2 |
| (Active region (42)) | | | |
| InₓGa₁₋ₓN | 760° C. | x = 0.05 | 0.4 |
| (Active region (42)) | | | |
| Al_{y}Ga_{1-y}N | 760° C. | y = 0.1 | 0.8 |
| (Active region (42)) | | | |
| InₓGa₁₋ₓN | 760° C. | x = 0.05 | 0.4 |
| (Active region (42)) | | | |
| . | | | |
| . | | | |
| . | | | |
| <<3 cycles>> | | | |
| . | | | |
| . | | | |
| . | | | |
| Al_{y}Ga_{1-y}N | 760° C. | y = 0.05 | 6 |
| (Last barrier (44)) | | | |
| GaN | 760° C. | | 6 |
| (Last barrier (44)) | | | |
| InₓGa₁₋ₓN | 760° C. | x = 0.05 | 6 |
| (Last barrier (44)) | | | |
| Al_{y}Ga_{1-x-y}InₓN | 820° C. | X = 0.1, y = 0.2 | 20 |
| (Electron blocking layer | | | |
| (52)) | | | |
| p-GaN | 900° C. | | 200 |
| (P-side contact region (52)) | | | |

To emit red light, a relatively high In content is required in the active region 42. However, it can be challenging to overcome crystal defects caused by a sharp lattice constant difference between the n-type semiconductor region 30 and the active region 42 with only the superlattice region. These issues can be resolved by introducing one or more strain control regions 38, 39, these issues can be resolved.

The strain control region 38,39 was grown in a hydrogen atmosphere, while the superlattice region 35 and the regions thereafter were grown in a nitrogen atmosphere. Growing in the hydrogen atmosphere improves the growth rate of the strain control region 38,39.

In the strain control regions 38, 39, the thickness of InₓGa₁₋ₓN is set to several tens of nm (e.g., 30 nm), with x in the composition being 0<x<0.3. The thickness of the GaN layer can be set to 10-200 nm, and the thickness of Al_{y}Ga_{1-y}N layer can be set to 1-20 nm, with y in the composition being 0.01<y<0.9. The difference in growth temperature (Δ T) between InₓGa₁₋ₓN and GaN is preferably at least 20 degrees. In other words, the growth temperature of GaN is set higher than that of InₓGa₁₋ₓN.

Compared to the examples presented in Table 8, the thickness of the lateral enhancement layer 36 has been reduced from 100 nm to 45 nm. When the roughness of the surface S is less than the examples in Table 8, the lateral enhancement layer 36 can be formed with a thickness of 50 nm or less.

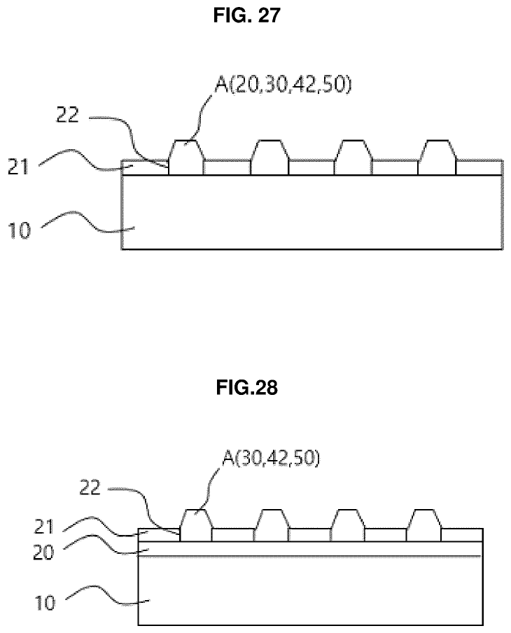

FIG. 27 illustrates another example of a semiconductor light emitting device according to the disclosure. Unlike the examples presented in FIGS. 1, 2, 18, and 22, a growth mask 21 (e.g., SiO₂) is provided on the growth substrate 10, and the semiconductor light emitting unit A (20, 30, 42, 50) grows from the exposed growth substrate 10 through an opening 22 formed in the growth mask 21. In this selective epitaxy process, the size of the opening 22, or the pattern size, can be adjusted to control the growth rate of the semiconductor light emitting unit A. If the size of the opening 22 is reduced, the growth rate increases, and the thickness of the semiconductor light emitting unit A grows larger. As a result, the active region 42 also increases in thickness, exhibiting the quantum confinement effect and allowing more indium to be incorporated, leading to emission of longer-wavelength light. When an InGaN layer is included below the active region 42, the indium content of this layer can be increased accordingly. While the semiconductor light emitting unit A is exemplified with a buffer region 20, an n-side contact region 30, an active region 42, and a p-side region 50, various other structures described earlier, as well as conventional semiconductor light emitting structures, can be applied.

FIG. 28 illustrates another example of a semiconductor light emitting device according to the disclosure. Unlike the example presented in FIG. 27, the buffer region 20 is located below the growth mask 21. Various structures of this type are disclosed in the applicant's international patent publication WO/2019/199144.

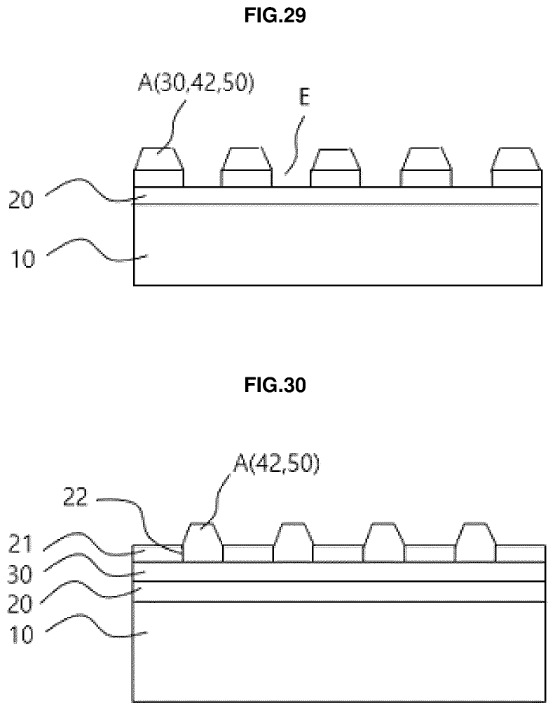

FIG. 29 illustrates another example of a semiconductor light emitting device according to the disclosure. Unlike the example presented in FIG. 28, the growth mask 21 is omitted, and a portion of the buffer region 20 is etched so that the etched region E does not allow growth, thereby replacing the growth mask 21 with the etched region E to enable selective growth of the semiconductor light emitting unit A. By adjusting the top surface size of the remaining buffer region 20 or the size of the etched region E, the emission wavelength of the active region 42 can be controlled. The growth mask 21 presented in FIG. 28 and the etched region E are collectively referred to as the growth inhibition regions (21, E). If a growth mask 21 is applicable in the disclosure, it can also be replaced by an etched region E. Additionally, an n-side contact region 30 can be grown on the buffer region 20 and subsequently etched to form the etched region E.

FIG. 30 illustrates another example of a semiconductor light emitting device according to the disclosure. Unlike the example presented in FIG. 28, the buffer region 20 and the n-side contact region 30 are located below the growth mask 21.

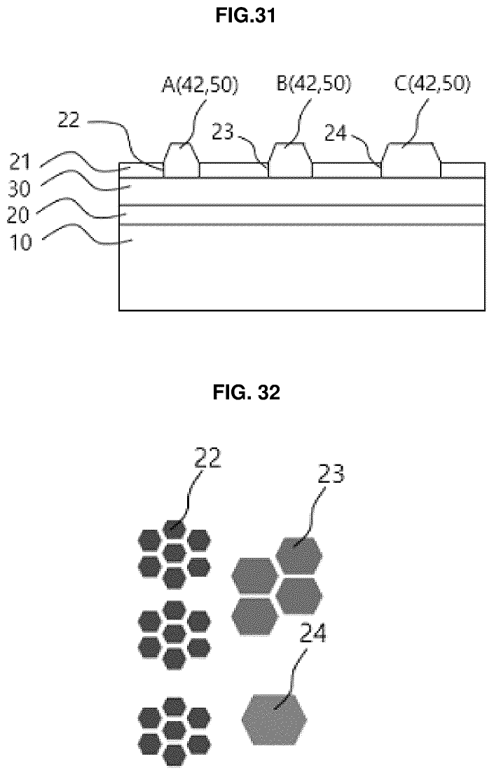

FIG. 31 illustrates another example of a semiconductor light emitting device according to the disclosure. Unlike the example presented in FIG. 28, the growth mask 21 is provided with openings 22, 23, and 24 of different sizes. The semiconductor light emitting units A, B, and C grow under the same growth conditions but vary in thickness and indium content of the active region 42, thereby emitting different wavelengths of light. For example, the semiconductor light emitting unit A grown in the smallest opening 22 emits the longest-wavelength light (e.g., red), the semiconductor light emitting unit C grown in the largest opening 24 emits the shortest-wavelength light (e.g., blue), and the semiconductor light emitting unit B grown in the medium-sized opening 23 emits light of an intermediate wavelength (e.g., green). The structure presented in FIG. 28 can be applied.

FIG. 32 illustrates an example of the opening pattern presented in FIG. 31. The smallest openings 22 are densely arranged (e.g., 6 per area), the largest openings 24 are sparsely arranged (e.g., 1 per area), and the medium-sized openings 23 are arranged at an intermediate density (e.g., 4 per area), thereby allowing control of the light intensity emitted from the semiconductor light emitting units A, B, and C.

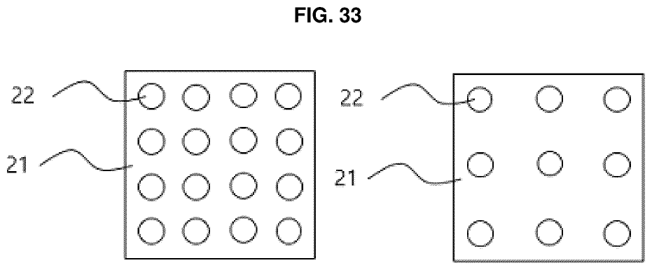

FIG. 33 illustrates another example of the arrangement of openings in a growth mask according to the disclosure. On the left side, the openings 22 of the growth mask 21 are arranged in a narrow spacing, while on the right side, they are arranged in a wider spacing. The size of the openings 22 remains the same. Under given growth conditions, increasing the spacing between the openings 22 allows for more sufficient source supply to each opening, resulting in thicker growth and higher indium incorporation. The effects described in FIG. 31 can also be achieved by applying varying spacing between openings 22 within a single growth mask 21. Similarly, replacing the openings 22 with remaining etched regions (see FIG. 28) follows the same principle. In the disclosure, adjusting the size and spacing of the growth inhibition regions 22 and E is collectively referred to as the pattern control of the growth inhibition regions 22 and E.

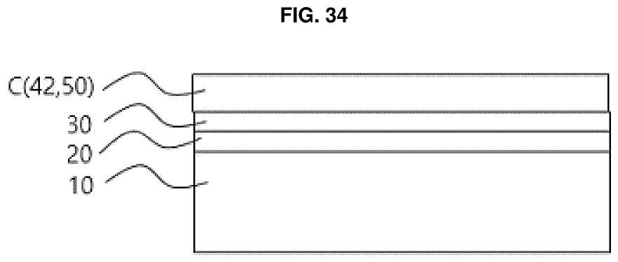

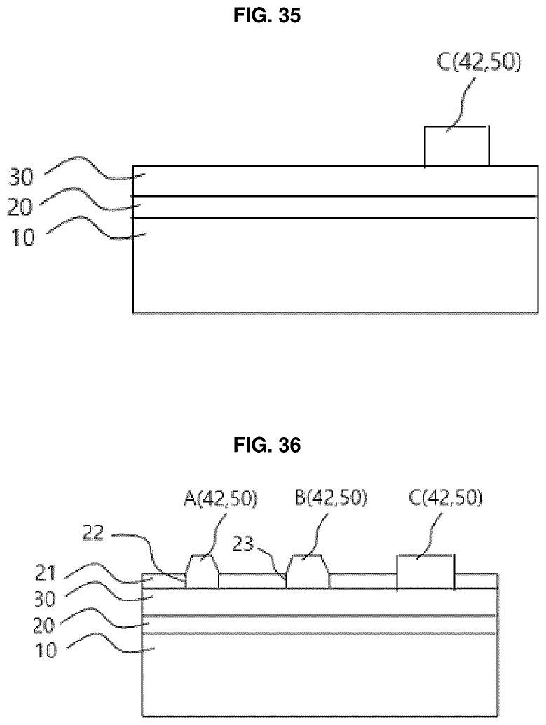

FIGS. 34 to 36 illustrate an example of a method for manufacturing a semiconductor light emitting device according to the disclosure. As shown in FIG. 34, the active region 42 and the p-side region 50 of the semiconductor light emitting unit C are grown on the n-side contact region 30 without forming a growth mask 21. Next, as shown in FIG. 35, a portion of the active region 42 and the p-side region 50 of the semiconductor light emitting unit C is removed through etching, exposing the n-side contact region 30. Finally, as shown in FIG. 36, the growth mask 21 is formed, then openings 22 and 23 are created, followed by a single growth process forming the semiconductor light emitting units A (42, 50) and B (42, 50). The growth conditions can be tuned such that the active region 42 of the semiconductor light emitting unit A grown in opening 22 emits red light, and the size of opening 23 can be adjusted to allow the semiconductor light emitting unit B to emit green light. Since there is a significant wavelength difference between red and blue, the blue light emitting semiconductor light emitting unit C can be formed not by selective growth but by pre-growing and then etching. Furthermore, this approach allows control over the size of semiconductor light emitting unit C regardless of its emission color. The active region 42 and p-side region 50 of semiconductor light emitting unit A can be grown first, or those of semiconductor light emitting unit B can be grown first.

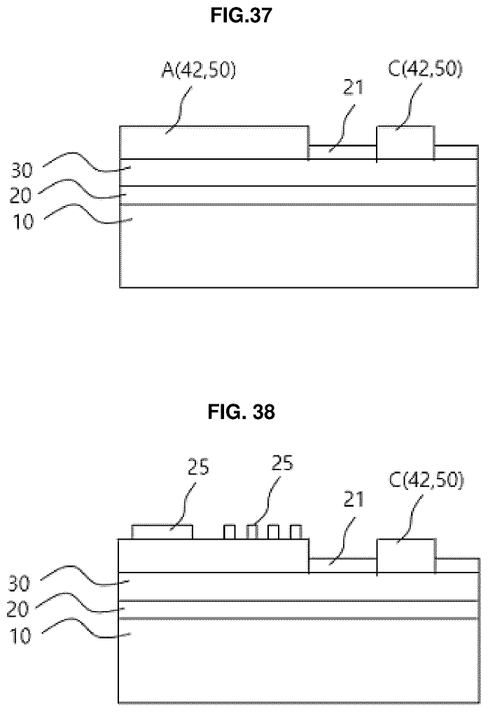

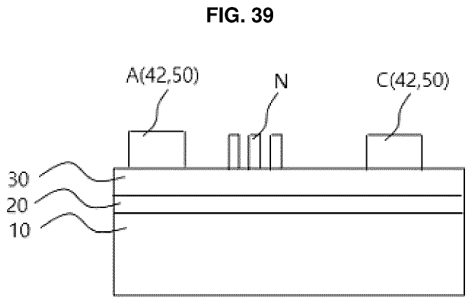

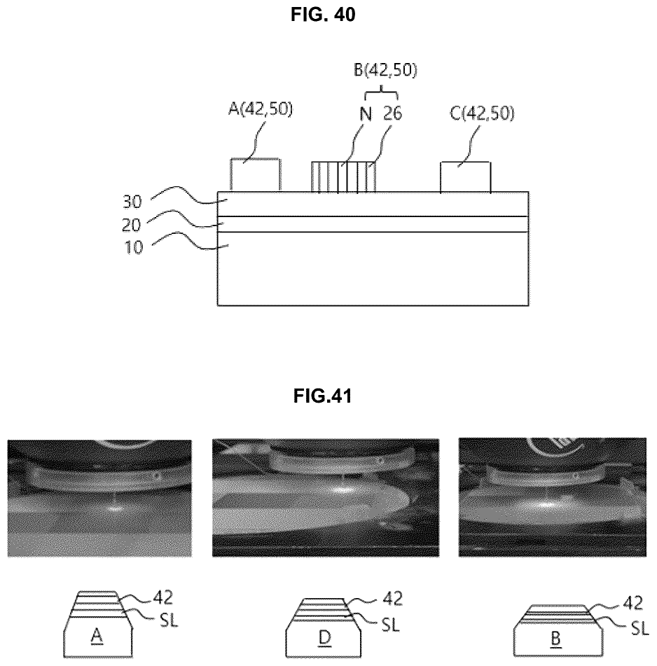

FIGS. 37 to 40 illustrate another example of a method for manufacturing a semiconductor light emitting device according to the disclosure. As shown in FIG. 37, a growth mask 21 is formed in the state shown in FIG. 35, and a semiconductor light emitting unit A (42, 50) is grown on the n-side contact region 30. Next, as shown in FIG. 38, an etching mask 25 is formed. Then, as shown in FIG. 39, a portion of the semiconductor light emitting unit A (42, 50) is retained while part of it is left as a nanowire structure N. Finally, as shown in FIG. 40, a cladding region 26 (e.g., SiO₂) is formed on the nanowire structure N, resulting in the formation of a nanowire-based semiconductor light emitting unit B (42, 50). For example, the semiconductor light emitting unit C can be designed to emit blue light, semiconductor light emitting unit A to emit red light, and semiconductor light emitting unit B to be formed as a nanowire structure, allowing the implementation of a three-color monolithic LED using two independent, non-interfering growth conditions. The size of semiconductor light emitting units A, B, and C can be adjusted as desired. The structures presented in FIGS. 27 and 28 can be applied to implement semiconductor light emitting units A, B, and C, but the presented example offers the advantage of using the n-side contact region 30 as a common electrode (Reference: Size-Dependent Strain Relaxation and Optical Characteristics of InGaN/GaN Nanorod LEDs, IEEE JOURNAL OF SELECTED TOPICS IN QUANTUM ELECTRONICS, VOL. 15, NO. 4, JULY/August 2009).

FIG. 41 presents an example of experimental results obtained using the method described in FIGS. 27 to 33. The semiconductor light emitting unit A on the left emits red light (e.g., 610 nm), the semiconductor light emitting unit B on the right emits green light (e.g., 550 nm), and the semiconductor light emitting unit D in the middle emits orange or yellow light (e.g., 580 nm). The experiment used hexagonal openings with side lengths of 14 μm, 23 μm, and 40 μm (see FIG. 32), with an opening-to-opening spacing of 10 μm. The results indicate that as the opening size decreases, the peak emission wavelength shifts toward longer wavelengths. As discussed earlier, smaller openings lead to faster growth rates, increasing the thickness of the superlattice region SL and the active region 42, while also allowing higher indium incorporation, resulting in longer wavelength emissions. Comparing the growth conditions of the active region 42 presented in Table 9, selective growth using openings of 14 μm with 10 μm spacing allows the supply ratio of In/(In+GaN) to be set at 60%, while the thickness of the well layer and barrier layer grows by approximately 50%, thereby enabling the implementation of a III-nitride semiconductor light emitting device emitting red light as presented in FIG. 41. This disclosure enables not only the selective growth of various colors within a single wafer but also the efficient production of III-nitride semiconductor light emitting devices emitting red light with less indium compared to non-selective growth processes.

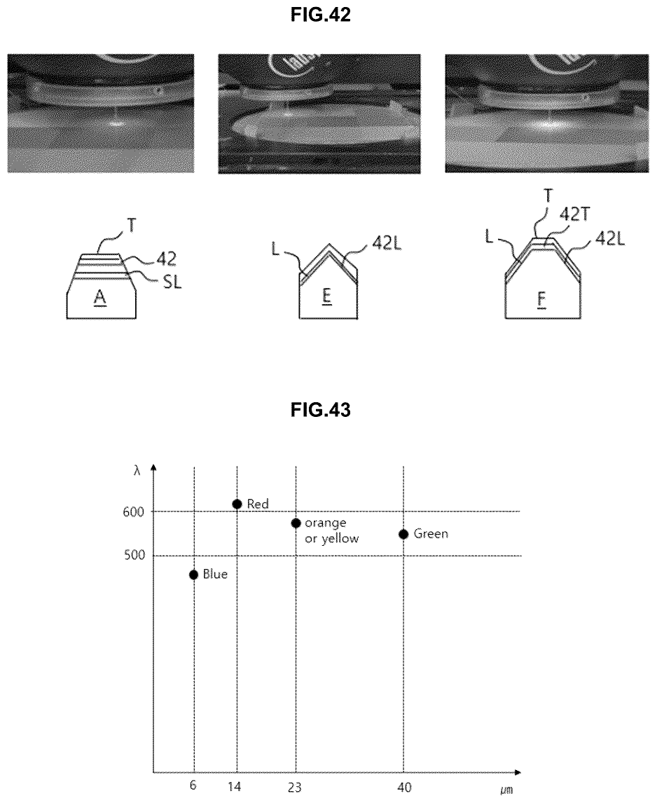

FIG. 42 illustrates another example of experimental results obtained using the method described in FIGS. 27 to 33. The semiconductor light emitting unit A on the left emits red light (e.g., 610 nm), the semiconductor light emitting unit E in the middle has a smaller width (e.g., 6 μm) compared to semiconductor light emitting unit A (opening size 14 μm) but emits blue light (e.g., 450 nm), and the semiconductor light emitting unit F on the right has the same width (23 μm) as the semiconductor light emitting unit D in FIG. 41, but instead of emitting orange to yellow light, it emits white light. The fact that semiconductor light emitting unit E emits shorter-wavelength light rather than longer-wavelength light contradicts previous experimental interpretations. This is likely due to the growth substrate 10 (see FIGS. 27 to 31), which is a C-plane sapphire substrate. In semiconductor light emitting units A, B, and D, the active region 42 grows on the top surface T (i.e., (0001) plane), whereas the active region 42L of semiconductor light emitting unit E forms on the side surface L (i.e., (11-22) plane) due to the smaller opening size. The growth rate on the (11-22) plane is slower (approximately ½ to 1/7 compared to the (0001) plane), and indium incorporation is relatively poor, resulting in blue light emission. As for semiconductor light emitting unit F, although its width (23 μm) is the same as that of semiconductor light emitting unit D, its opening spacing (see FIG. 33) was set to 30 μm instead of 10 μm. Assuming uniform gas supply inside the MOCVD equipment, increasing the spacing leads to a higher concentration of growth gas around semiconductor light emitting unit F, resulting in faster growth. Consequently, semiconductor light emitting unit F grows taller than semiconductor light emitting unit D, forming active regions 42T on the top surface T and 42L on the side surface L. The active region 42T emits orange or yellow light, while the active region 42L emits blue light. Since orange to yellow and blue are complementary colors, semiconductor light emitting unit F appears white.

FIG. 43 summarizes the experimental results presented in FIGS. 41 and 42 as a graph. In general, as the size of openings 22, 23, and 24 (see FIG. 32) decreases, the peak emission wavelength shifts toward longer wavelengths. However, under certain growth conditions, when the opening size reaches a threshold where the active region 42L forms on the side surface L (i.e., (11-22) plane), semiconductor light emitting units A, E, and F (see FIG. 42) exhibit shorter-wavelength emission compared to active regions 42T formed on the top surface T. This graph also demonstrates that by growing active regions 42T and 42L separately on the top and side surfaces and adjusting growth conditions and the pattern of the growth inhibition regions 22 and E, a single semiconductor light emitting unit F can emit white light.

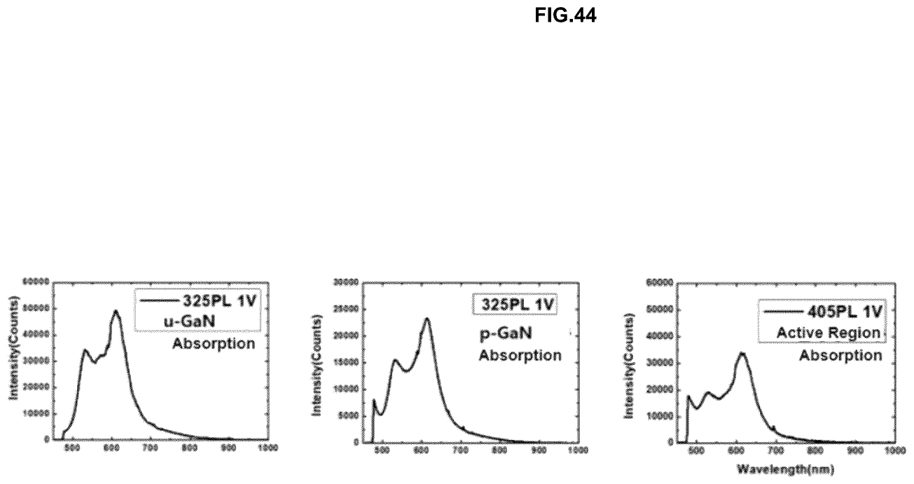

FIG. 44 shows an example of photoluminescence (PL) experiment results in the disclosure, which shows, from left to right, the absorption results of u-GaN with excitation light of a wavelength of 325 nm, the absorption results of p-GaN with excitation light of a wavelength of 325 nm, and the absorption results of the active layer with excitation light of a wavelength of 405 nm. In all cases, only very weak and identical deep level emission was measured. Even when light was selectively absorbed in u-GaN, p-GaN, and the active layer, the same very weak emission spectrum was observed. There was no peak shift due to bias application (since the bias is applied only to the active layer, indicating that it is not active emission). IN the case of 405 nm excitation, only a slight decrease in intensity was observed with reverse bias application (indicating the presence of the same deep level throughout the sample, including the active region).

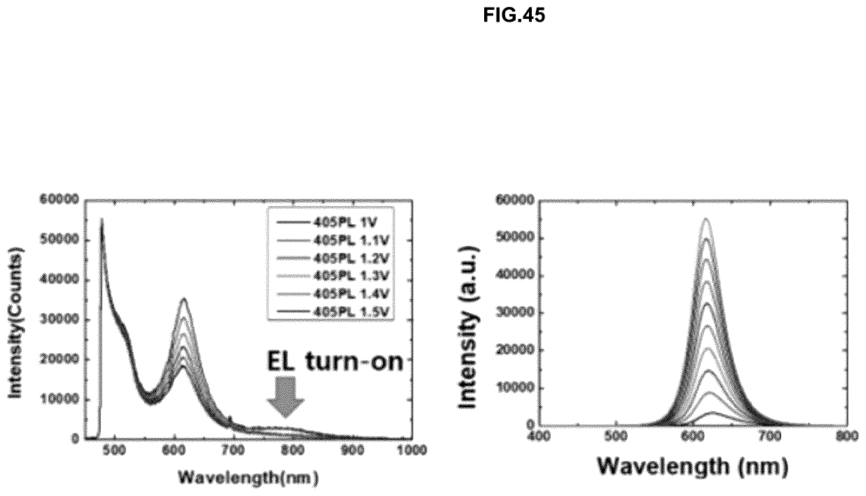

FIG. 45 shows an example of field luminescence (EL) experiment results in the disclosure. The EL resulting from current injection starts at much longer wavelengths compared to photoluminescence (PL) and exhibits an intensity that is several tens of times greater than that of PL at longer wavelengths. Additionally, photoluminescence corresponding to EL was not observed even in low-temperature PL or high-excitation PL. The operating voltage of EL is smaller than the minimum operating voltage (hv/e) obtained from the emission wavelength. These results indicate that PL emission and EL emission occur in spatially separate and distinct regions.

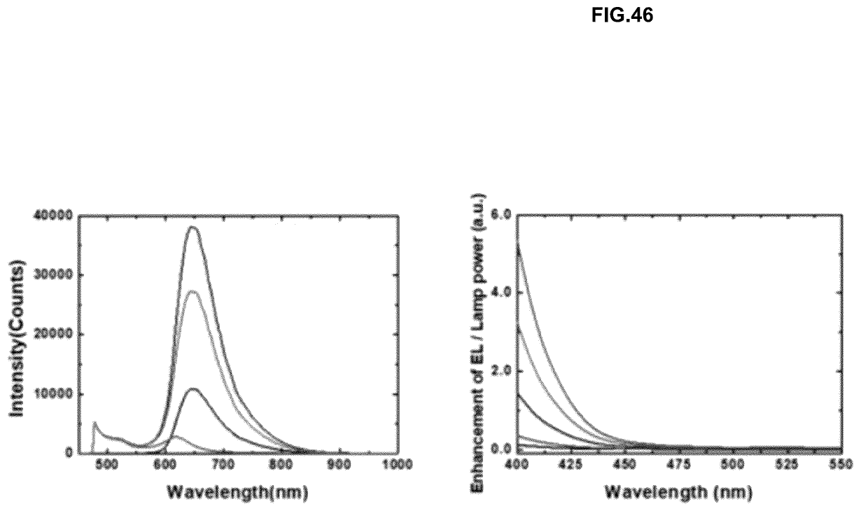

FIG. 46 shows an example of field luminescence (EL) experiment results with a laser being added according to the disclosure. When a laser is added while the EL is on, the intensity of EL increases dramatically (by more than three times). When only the laser is irradiated, very weak, different PL is observed as described above. When excitation light is added to the EL process which occurs by applying a forward voltage, the intensity of EL, of which level depends on the wavelength of the excitation light, increases non-linearly. The laser used here has a wavelength of 405 nm, and its energy is greater than the energy of the well layer but less than the energy of the barrier layer or the p-GaN and n-GaN layers. That is to say, the laser is selectively absorbed only in the well layer.

To summarize the experiment results from FIGS. 44 to 46, (i) EL is observed, but PL is not; (ii) Absorption by the excitation laser during PL occurs in the quantum well layer (this is experimentally confirmed from photocurrent measurements); (iii) In PL, laser absorption occurs in the quantum well layer, but the emission from the quantum well layer is not observed; (iv) The quantum well layer has a high density of non-radiative recombination centers, leading to very low photoluminescence efficiency; and (v) EL and PL occur in different regions that are spatially separated from each other.

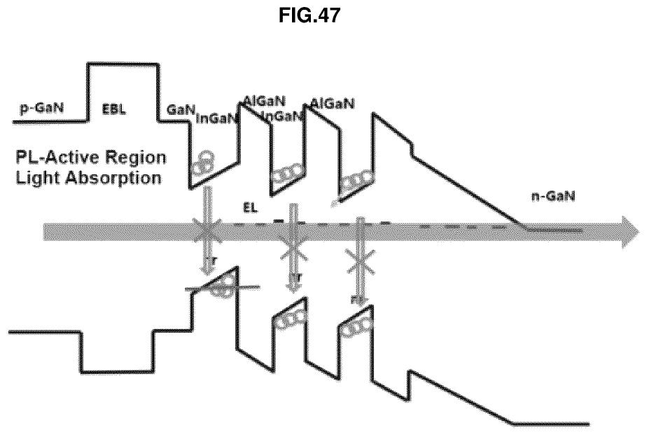

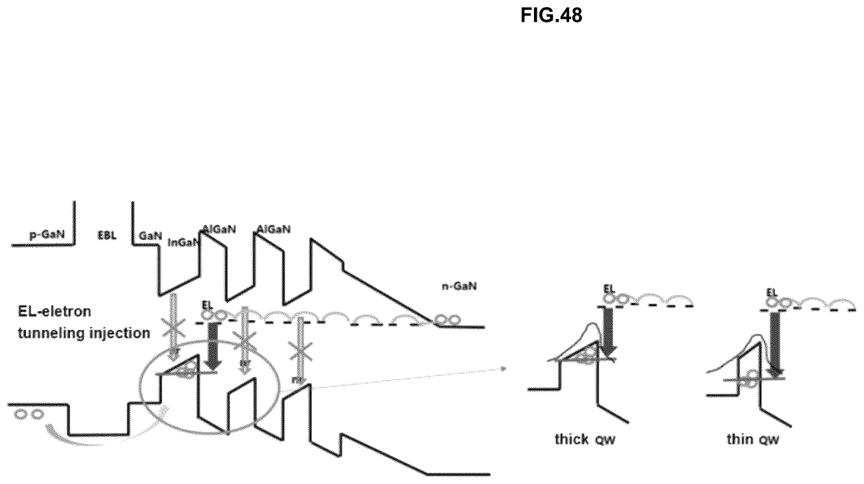

FIG. 47 schematically illustrates the emission mechanism that is consistent with these findings, that is, luminescence through tunneling injection (Paper: Tunnel Injection and Power Efficiency of InGaN/GaN Light emitting Diodes; ISSN 1063-7826, Semiconductors, 2013, Vol. 47, No. 1, pp. 127-134. ©Pleiades Publishing, Ltd., 2013). Electrons are injected by tunneling into a low-energy state in the AlGaN barrier layer. It is believed that in EL, electron-hole recombination occurs by avoiding the quantum well layer with a high density of non-radiative recombination centers. In addition, the barrier has a low density of non-radiative recombination centers, so that high-efficiency, low-energy (longer wavelength) light emission is possible. Further, EL can be observed with a low operating voltage (see FIG. 48).

It would be worthy of noting what enables emission through tunneling injection in the semiconductor light emitting device according to the disclosure, which differs from the conventional GaN-based LEDs. As shown in FIG. 21, when a lateral enhancement layer 36 or 37 is not introduced between the active region 42 and its nearest superlattice region 35, such emission occurs. However, this is not the case when the lateral enhancement layer 36 or 37 is introduced. Therefore, aside from the understanding that the active region 42 grown on the semi-polar plane can increase indium injection when the lateral enhancement layer 36 or 37 is not present, tunneling injection becomes possible by growing the active region 42 without recovering the defects created by the rough surface S through the lateral enhancement layer 36 or 37.

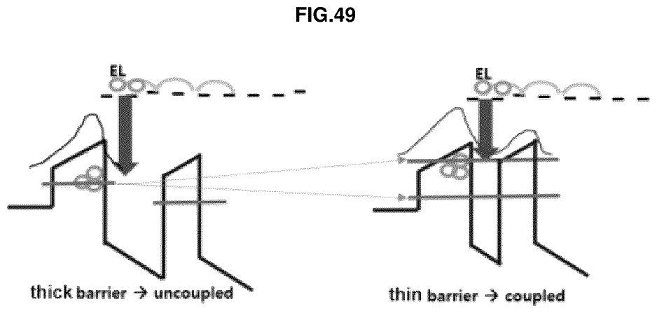

As shown in FIG. 49, as the barrier thickness decreases, coupling occurs between the last quantum well (QW) and the second-to-last QW. This splits the energy state of the QW into two, with the ground state energy becoming lower (the wavelength becomes longer) (Paper: Effect of electric fields on excitons in a coupled double-quantum-well structure; PHYSICAL REVIEW B VOLUME 36, NUMBER 8 15 Sep. 1987-1). This finding is consistent with the experiment results shown in FIG. 24, which states that ‘as the barrier layer in the active region 42 and the well layer get thicker, the wavelength gets longer’. Therefore, according to the experiment results and interpretation of this disclosure, the emission wavelength can be controlled to a longer wavelength by making the last barrier thinner and the last well layer thicker.

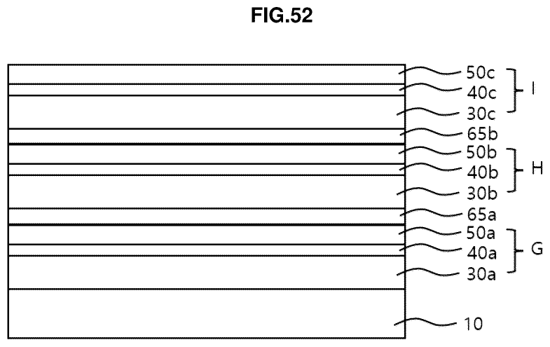

FIG. 52 illustrates another example of a III-nitride semiconductor light emitting structure or device according to the disclosure. The light emitting device includes a first semiconductor light emitting unit G, a second semiconductor light emitting unit H, and a third semiconductor light emitting unit I. Each semiconductor light emitting unit G, H, and I can emit light of different wavelengths, and can be configured, for example, to emit blue-green-red light or red-green-blue light. The first semiconductor light emitting unit G includes: a first semiconductor region 30a having a first conductivity, an active region 40a that generates light, and a second semiconductor region 50a having a second conductivity different from the first conductivity. The second semiconductor light emitting unit H includes: a first semiconductor region 30b having a first conductivity, an active region 40b that generates light, and a second semiconductor region 50b having a second conductivity different from the first conductivity. The third semiconductor light emitting unit I includes: a first semiconductor region 30c having a first conductivity, an active region 40c that generates light, and a second semiconductor region 50c having a second conductivity different from the first conductivity. The first semiconductor regions 30a, 30b, and 30c can be configured to include the previously described n-side contact region 30, while the second semiconductor regions 50a, 50b, and 50c can be configured to include the previously described p-side contact region 52. The active regions 40a, 40b, and 40c can be designed in accordance with the emission wavelength, and may adopt an InGaN/(In) GaN multiple quantum well structure. For red light emission, the previously described active region 42 in this disclosure can be applied. Additionally, the first semiconductor regions 30a, 30b, and 30c can be configured to include the p-side contact region 52, while the second semiconductor regions 50a, 50b, and 50c can be configured to include the n-side contact region 30. Preferably, a first insulation layer 65a is provided between the first semiconductor light emitting unit G and the second semiconductor light emitting unit H, and a second insulation layer 65b is provided between the second semiconductor light emitting unit H and the third semiconductor light emitting unit I. If insulation layers 65a and 65b are made of materials such as SiO₂ or SiNx, the growth of the first semiconductor light emitting unit G must be interrupted to form the first insulation layer 65a externally using the growth equipment (e.g., MOVCD), followed by the growth of the second semiconductor light emitting unit H, which presents a challenge (the same applies to the second insulation layer 65b). To address this issue, insulation layers 65a and 65b can be formed using materials compatible with the semiconductor light emitting units G, H, and I, such as AlN, Fe-doped GaN, C-doped GaN, Cr-doped GaN (transition metals Mn, Co, and Fe), or using ion implantation techniques. Buffer region 20 (see FIG. 2) can be provided between the growth substrate 10 and the first semiconductor light emitting unit G, between the first insulation layer 65a and the second semiconductor light emitting unit H, and between the second insulation layer 65b and the third semiconductor light emitting unit I. Methods for forming materials such as AlN, Fe-doped GaN, C-doped GaN, and Cr-doped GaN (transition metals Mn, Co, and Fe) can be found in various research papers, including: Electrical and Optical Properties of Carbon-Doped GaN Grown by MBE on MOCVD GaN Templates Using a CCI4 Dopant Source, presented at the 2002 MRS Spring Meeting. Structural and Optical Properties of Cr-Doped Semi-Insulating GaN Epilayers, Applied Physics Letters, Vol. 93, 113507 (2008). Mechanism Leading to Semi-Insulating Property of Carbon-Doped GaN: Analysis of Donor Acceptor Ratio and Method for its Determination, Journal of Applied Physics, Vol. 130, 185702 (2021). Semi-Insulating C-Doped GaN and High-Mobility AlGaN/GaN Heterostructures Grown by Ammonia Molecular Beam Epitaxy, Applied Physics Letters, Vol. 75, 953 (1999). Semi-Insulating GaN by Fe-Doping in Hydride Vapor Phase Epitaxy Using a Solid Iron Source.

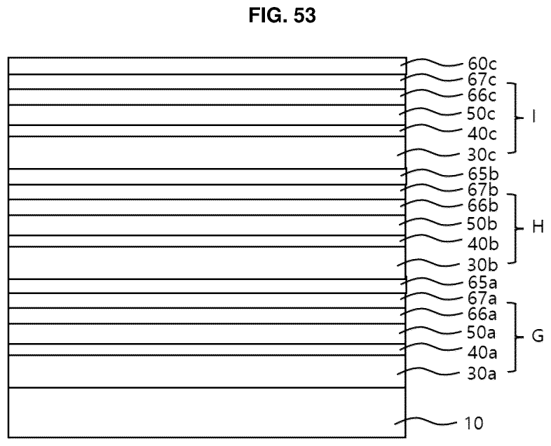

FIG. 53 illustrates another example of a III-nitride semiconductor light emitting structure or device according to the disclosure. In addition to the structure presented in FIG. 52, first internal current spreading layers 66a, 67a, second internal current spreading layers 66b, 67b, and third internal current spreading layers 66c, 67c are provided above each of the second semiconductor regions 50a, 50b, and 50c. These layers are introduced to improve current spreading in the p-type second semiconductor regions 50a, 50b, and 50c, which have low current spreading capabilities. Above the third internal current spreading layer 66c, 67c, a third external current spreading layer 60c is additionally provided. This layer may be composed of transparent conductive oxide (TCO) such as ITO, or reflective metals such as Al, Au, Ag, or alloys containing reflective metals. The third external current spreading layer 60c corresponds to the previously described current spreading electrode 60. Either the third external current spreading layer 60c or the third internal current spreading layer 66c, 67c can be omitted. Similarly, a first external current spreading layer (not shown) can be provided above the first semiconductor light emitting unit G, and a second external current spreading layer (not shown) can be provided above the second semiconductor light emitting unit H. When forming internal current spreading layers 66a, 67a, 66b, 67b, 66c, 67c using transparent conductive oxide (TCO) such as ITO, complications similar to those encountered during insulation layer formation (65a, 65b) may arise. Therefore, it is preferable to use materials that can be formed in the same manner as semiconductor light emitting units G, H, and I. This approach enables the fabrication of III-nitride semiconductor light emitting structures or devices emitting various wavelengths within a single epitaxial growth process. For example, internal current spreading layers 67a, 67b, 67c can be formed from n-GaN, similar to the first semiconductor regions 30a, 30b, and 30c. Internal current spreading layers 66a, 66b, 66c can be configured as tunnel junction regions (e.g., nGaN/PGaN), each having a thickness of 50 nm or less and a doping concentration of at least 102°. In this context, internal current spreading layers 67a, 67b, 67c function as current spreading enhancement regions for improving current spreading in second semiconductor regions 50a, 50b, 50c, while internal current spreading layers 66a, 66b, 66c serve as current supply regions that enable current flow from the internal current spreading layers 67a, 67b, 67c to the second semiconductor regions 50a, 50b, and 50c.

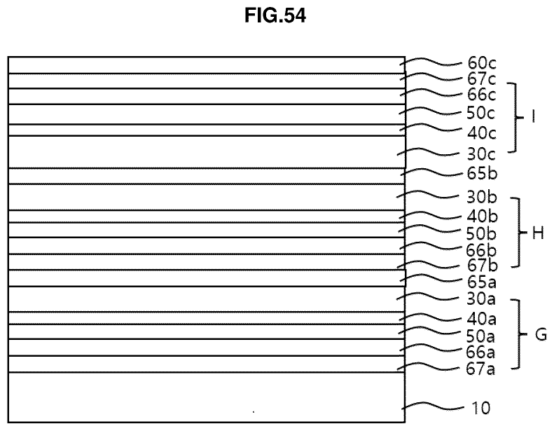

FIG. 54 illustrates another example of a III-nitride semiconductor light emitting structure or device according to the disclosure. In the first semiconductor light emitting unit G and the second semiconductor light emitting unit H, the positions of the first semiconductor regions 30a, 30b and the second semiconductor regions 50a, 50b are swapped relative to the active regions 40a, 40b. When the second semiconductor regions 50a, 50b have p-type conductivity, internal current spreading layers 67a and 66a are sequentially positioned beneath the second semiconductor region 50a, extending from the growth substrate 10. Similarly, internal current spreading layers 67b and 66b are sequentially positioned beneath the second semiconductor region 50b. The positions of the first semiconductor region 30c and the second semiconductor region 50c in the third semiconductor light emitting unit I can also be swapped. However, since the epitaxial process is completed after the growth of the third semiconductor light emitting unit I, followed by the electrode formation process, the topmost layer of the third semiconductor light emitting unit I is configured as a second semiconductor region 50c with p-type conductivity. After completing the epitaxial process, the third external current spreading layer 60c is formed as necessary.

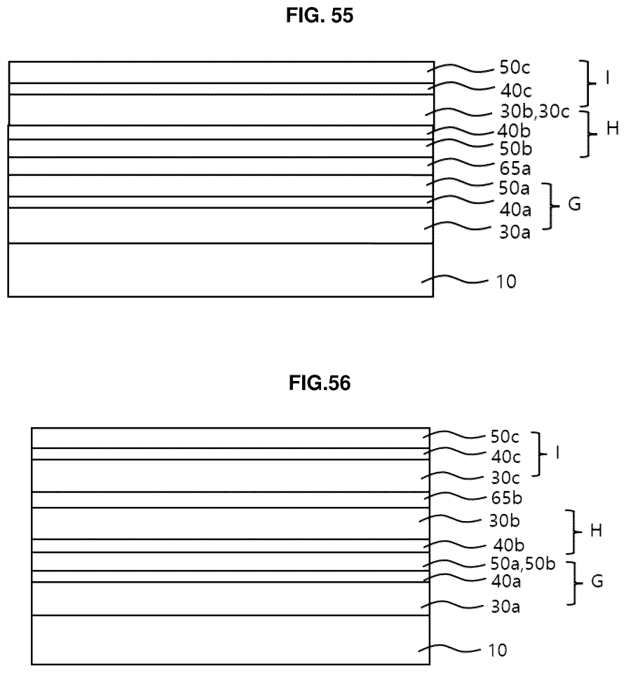

FIG. 55 illustrates another example of a III-nitride semiconductor light emitting structure or device according to the disclosure. Unlike the example presented in FIG. 52, the second insulation layer 65b is omitted, and the positions of the first semiconductor region 30b and the second semiconductor region 50b in the second semiconductor light emitting unit G are swapped. Additionally, the first semiconductor region 30b of the second semiconductor light emitting unit H and the first semiconductor region 30c of the third semiconductor light emitting unit I are shared. This configuration enables the control of the first semiconductor regions 30b and 30c through a single electrode, as described later.

FIG. 56 illustrates another example of a III-nitride semiconductor light emitting structure or device according to the disclosure. Unlike the example presented in FIG. 52, the second semiconductor regions 50a and 50b in the first semiconductor light emitting unit G and the second semiconductor light emitting unit H are shared. Similar to FIG. 55, the positions of the first semiconductor region 30b and the second semiconductor region 50b in the second semiconductor light emitting unit H are swapped.

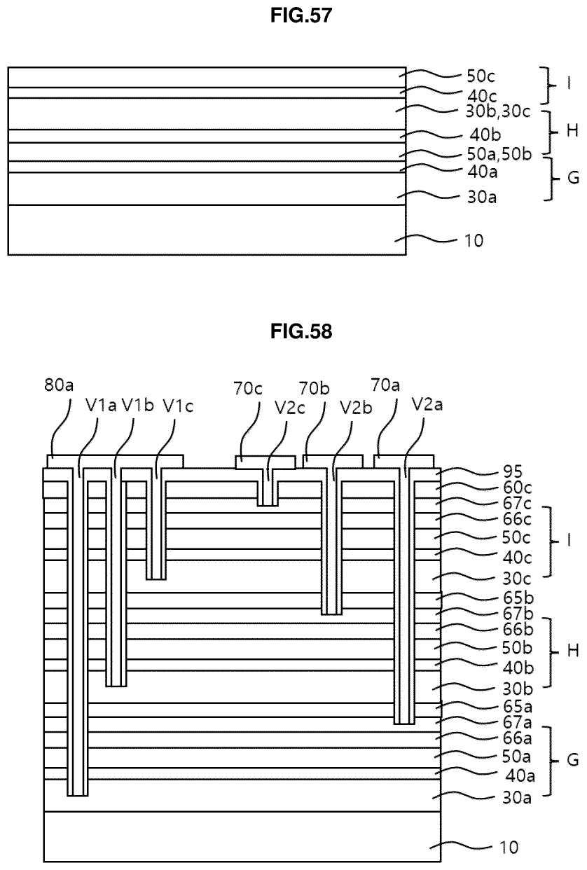

FIG. 57 illustrates another example of a III-nitride semiconductor light emitting structure or device according to the disclosure. Unlike the example presented in FIG. 52, insulation layers 65a and 65b are omitted, and a combination of the examples in FIGS. 55 and 56 is applied. As a result, the second semiconductor regions 50a and 50b in the first and second semiconductor light emitting units G and H are shared, and the first semiconductor regions 30b and 30a in the second and third semiconductor light emitting units H and I are also shared. Furthermore, the positions of the first semiconductor region 30b and the second semiconductor region 50b in the second semiconductor light emitting unit H are swapped.

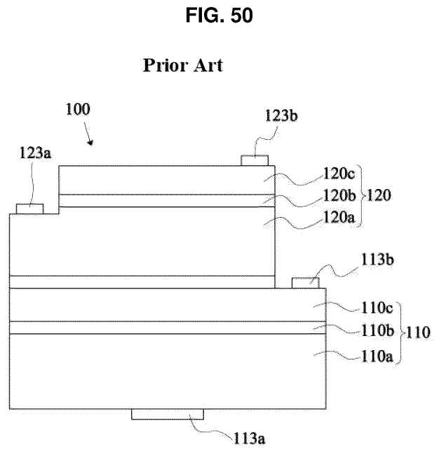

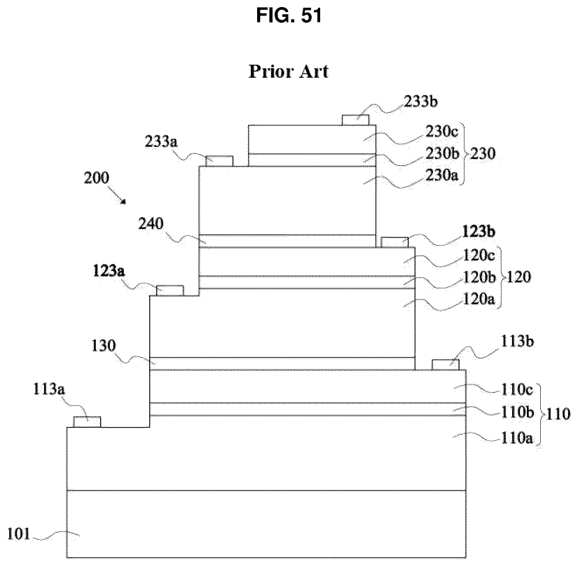

FIG. 58 illustrates another example of a III-nitride semiconductor light emitting structure or device according to the disclosure. In addition to the example presented in FIG. 53, electrodes 70a, 70b, 70c, and 80a are formed. A passivation layer 95 (e.g., SiO₂) is provided between the electrodes 70a, 70b, 70c, 80a and the third semiconductor light emitting unit I, serving as both an insulation layer and a device protection layer. The second common electrode 80a is configured as a shared electrode for the first semiconductor regions 30a, 30b, 30c. Individual pads can be formed as needed. For electrical connections, via holes V1a, V1b, V1c for each first semiconductor region 30a, 30b, 30c and via holes V2a, V2b, V2c for each second semiconductor region 50a, 50b, 50c are established. For the third semiconductor light emitting unit I, the via hole V1c is formed up to the first semiconductor region 30c, with the second common electrode 80a extending to electrically connect to the first semiconductor region 30c. Meanwhile, the via hole V2c is formed up to the first internal current spreading layer 67c, and the first third electrode 70c is electrically connected to this layer. If the third internal current spreading layers 66c, 67c are omitted, the first third electrode 70c is connected to the third external current spreading layer 60c (if present, the third external current spreading layer 60c can be omitted). If the third external current spreading layer 60c is also absent, direct electrical contact is established with the second semiconductor region 50c. The same applies to the first and second semiconductor light emitting units G, H. The electrical connections illustrated in FIGS. 50 and 51 can be applied. However, when the device dimensions become extremely small (below 50 μm), securing sufficient electrode area becomes difficult. If the growth substrate 10 (see FIG. 58) is removed or a conductive growth substrate 10 is used, one of the electrodes 70, 80 may be formed on the rear side of the growth substrate 10. Additionally, instead of using the second common electrode 80a, the first electrodes 70a, 70b, 70c can be configured as a single common electrode in the form of a pad.

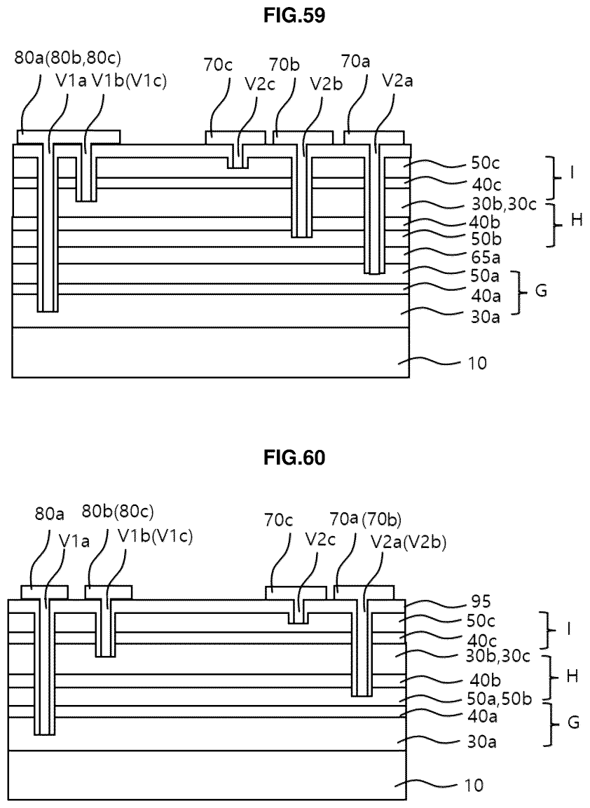

FIG. 59 illustrates another example of a III-nitride semiconductor light emitting structure or device according to the disclosure. In addition to the example presented in FIG. 55, electrodes 70a, 70b, 70c, and 80a are formed. The second common electrode 80a serves as a shared electrode for the second electrodes 80b and 80c. Since the first semiconductor regions 30b and 30c in the semiconductor light emitting units H and I are shared, electrodes 80b and 80c are established through a single via hole V1b (V1c), reducing the total number of via holes by one compared to the example presented in FIG. 58.

FIG. 60 illustrates another example of a III-nitride semiconductor light emitting structure or device according to the disclosure. In addition to the example presented in FIG. 57, the first electrodes 70a and 70b are shared as a common electrode, and the second electrodes 80b and 80c are also shared as a common electrode, thereby reducing the number of via holes by two. However, independent control of the three semiconductor light emitting units G, H, and I is not possible.

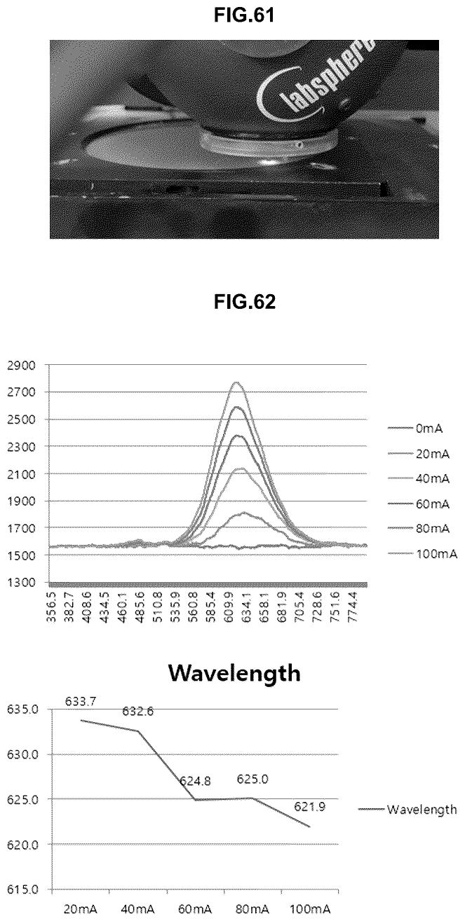

FIGS. 61 and 62 illustrate experimental results demonstrating the actual implementation of the III-nitride semiconductor light emitting structures or devices described in FIGS. 52 to 60. The results show wafer-level electroluminescence (EL) measurements of the third semiconductor light emitting unit I, applying the red light emitting semiconductor structure 42 (e.g., Table 9). The red emission wavelength was successfully observed.

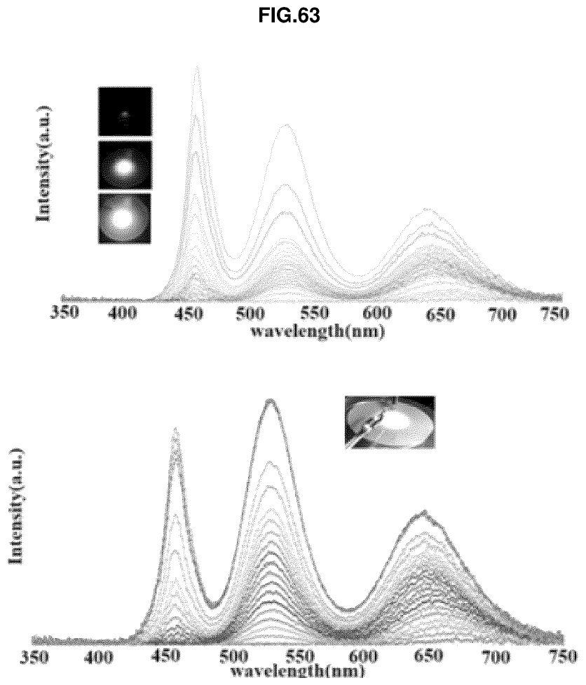

FIG. 63 presents additional experimental results demonstrating the actual implementation of the III-nitride semiconductor light emitting structures or devices described in FIGS. 52 to 60. The wafer-level indium ball contact EL measurement results show successful emission of blue, green, and red light.

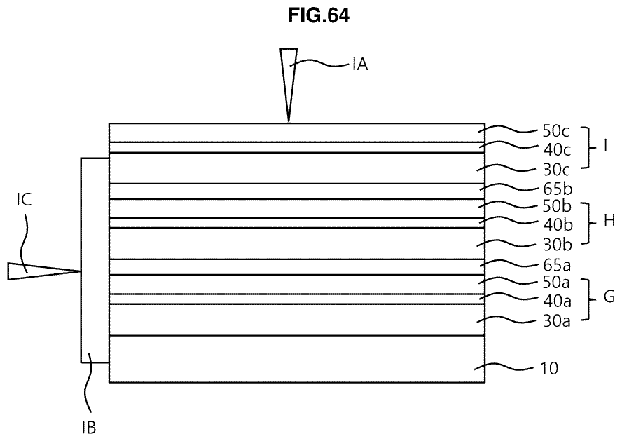

FIG. 64 illustrates an example of a method for measuring the wafer state of III-nitride semiconductor light emitting structures or devices described in FIGS. 52 to 57.

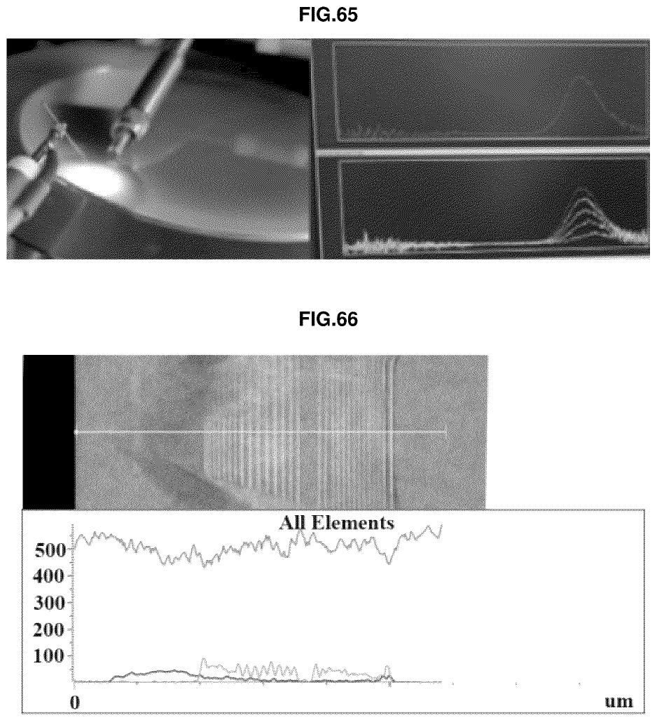

Using the III-nitride semiconductor light emitting structure presented in FIG. 52 as an example, it explains an EL measurement process for the third semiconductor light emitting unit I that emits red light. Conventionally, as shown in FIG. 51, EL is measured by exposing the first semiconductor regions 110a, 120a, 230a and the second semiconductor regions 110c, 120c, 230c of the semiconductor light emitting units 110, 120, 230. However, it was discovered that EL of the third semiconductor light emitting unit I could be measured without this exposure process. As illustrated, the measurement process involves attaching a conductive pad IB (e.g., an indium ball) to the first semiconductor region 30c of the third semiconductor light emitting unit I. Since the first semiconductor region 30c is less than 10 μm thick, the conductive pad IB extends at least over the second semiconductor light emitting unit H. It can also be attached across the first semiconductor light emitting unit G and the second semiconductor region 50c. Using probes or measurement electrodes IC and IA, EL can be measured without interference from the active regions 40a of the first semiconductor light emitting unit G or 40b of the second semiconductor light emitting unit H, allowing precise measurement of the active region 40c in the third semiconductor light emitting unit I. The actual measurement process is shown in FIG. 65. Since electrical current follows the path of least resistance, the second insulation layer 65b beneath the third semiconductor light emitting unit I ensures that the current flows only between the second semiconductor region 50c and the first semiconductor region 30c. This enables the EL measurement of the third semiconductor light emitting unit I without interference, even if the conductive pad IB extends over the second semiconductor light emitting unit H or the first semiconductor light emitting unit G. In the case of FIG. 55, where no insulation layer 65b is provided between the second and third semiconductor light emitting units H and I, or FIG. 57, where no insulation layer 65b is present between H and I and no insulation layer 65a is present between G and H, EL of the third semiconductor light emitting unit I can still be measured based on the same principle—that current follows the path of least resistance. Additionally, by injecting low current, EL of the third semiconductor light emitting unit I can be measured. As current increases, saturation occurs in the third semiconductor light emitting unit I, causing the remaining current to flow into the second semiconductor light emitting unit H, allowing characterization of its EL properties. In the case of FIG. 57, further increasing the current enables characterization of the EL properties of the first semiconductor light emitting unit G.

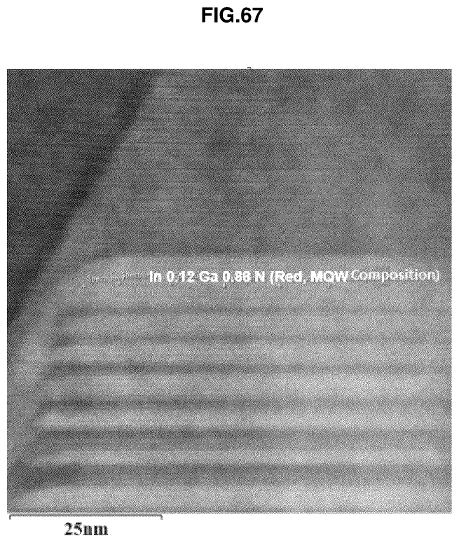

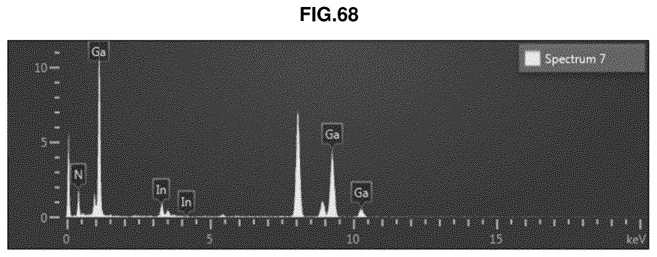

FIGS. 66 to 68 show other examples of measurement results in the disclosure. FIG. 33 presents ESD analysis results, and FIGS. 67 to 68 present point composition analysis results. As a result of measuring 7 points on the last quantum well layer among the 3-cycle quantum well layers of the active area 42 presented in FIG. 22, the contents (x) of indium (In) were measured as 12.90%, 11.26%, 10.94%, 11.49%, 12.25%, 10.89%, and 13.42%, respectively. The average value of the contents was approximated to 12% (rounded up from 11.88%), falling in the range of 10 to 20%. From these results, it was confirmed that the quantum well layer of the red-emitting III-nitride semiconductor light emitting device according to the disclosure has an indium content that is typical of quantum wells emitting green or blue light based on the measured value, but it actually emits red light. The theoretical explanation consistent with these results seems to be related to the experiment results described in FIGS. 44 to 46. Therefore, according to these measurement results, the III-nitride semiconductor light emitting device according to the disclosure can be defined as having a quantum well layer of InₓGa₁₋ₓN with an indium content (x) value (as measured) theoretically expected to emit blue light (approximately 0.1) or green light (approximately 0.2) but actually emitting red light. In the example shown, the device should theoretically emit light of 500 nm or less, but it actually emits light of 600 nm or more. A broad interpretation of this is that it is possible to manufacture a III-nitride semiconductor light emitting device that emits light with a wavelength of 600 nm or more from an active region having a quantum well layer with an indium content (x) corresponding to an emission wavelength below 600 nm (further below 500 nm).

Returning to FIGS. 41 to 43, FIG. 41 presents an example where hexagonal openings with side lengths of 14 μm, 23 μm, and 40 μm (with an inter-opening spacing of 10 μm) are used to emit red (e.g., 610 nm), orange-yellow (e.g., 580 nm), and green (e.g., 550 nm) light, respectively. Meanwhile, FIG. 42 demonstrates an example using hexagonal openings with side lengths of 14 μm, 6 μm, and 23 μm to emit red (e.g., 610 nm), blue (e.g., 450 nm), and white light, with an inter-opening spacing of 30 μm. These results indicate that by properly combining light emitting units, white light can be achieved-either as an inherent white emission, by combining blue, green, and red, or by utilizing complementary colors (e.g., orange and blue). FIG. 32 illustrates that by growing these structures adjacently, they can function as a unit, package, cell, or pixel, allowing for independent color emission, white light generation, or integration with liquid crystals for display applications. For example, using the 23 μm opening from FIG. 41, an orange-yellow light emitting unit D (e.g., 580 nm) can be formed, while using the 6 μm opening from FIG. 42, a blue light emitting unit E (e.g., 450 nm) can be grown alongside, achieving white light emission through their complementary relationship. Similarly, an arrangement utilizing the 14 μm opening for red light emitting unit A (e.g., 610 nm), the 40 μm opening for green light emitting unit B (e.g., 550 nm), and the 6 μm opening for blue light emitting unit E (e.g., 450 nm) can also be configured to produce white light. A unique characteristic of this configuration is that, contrary to the trend observed in FIG. 41 (where smaller openings result in longer wavelength emissions), the smaller opening of light emitting unit E actually leads to the emission of shorter-wavelength blue light. This selective growth approach allows for the formation of yellow light emitting unit D (23 μm) and blue light emitting unit E (6 μm) or green light emitting unit B (40 μm), red light emitting unit A (14 μm), and blue light emitting unit E (6 μm), effectively producing white light while ensuring the openings (or etched regions, as per FIG. 29) follow the prescribed order of sizes.

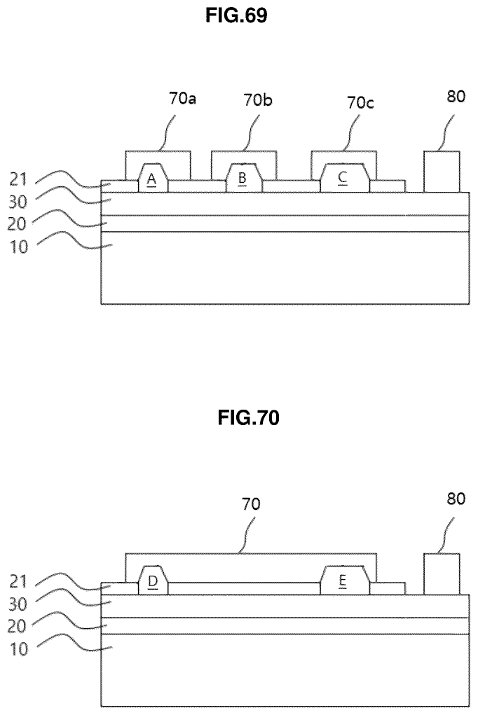

FIG. 69 illustrates another example of a III-nitride semiconductor light emitting device based on the structure presented in FIG. 31. It incorporates electrodes 70a, 70b, 70c, and 80, where electrodes 70a, 70b, and 70c are formed while retaining the growth mask 21 for selective epitaxy, while electrode 80 is formed by removing the growth mask 21, implementing a flip-chip structure. Electrodes 70a, 70b, and 70c contain reflective metals (e.g., Al, Au, Ag) corresponding to the emission wavelengths of semiconductor light emitting units A, B, and C. The principles demonstrated in FIGS. 41 and 42 apply to this configuration, and it allows for the possibility of using two p-side electrodes instead of three. The growth mask 21 can be removed, with additional insulation layers (e.g., SiO₂, polyimide) formed separately. Alternatively, the growth mask 21 itself may function as an insulation or passivation layer.

FIG. 70 illustrates another example of a III-nitride semiconductor light emitting device incorporating the principles shown in FIGS. 41 and 42. Here, an orange-yellow light emitting unit D and a blue light emitting unit E are formed, with a single electrode 70 used to apply power, utilizing the complementary color relationship to achieve white light emission. Additionally, in the case of FIG. 69, electrodes 70a, 70b, and 70c can be powered individually to produce white light or configured as a single electrode to supply power and emit white light. While the first electrode 70 can be divided into two parts, in a flip-chip configuration, the first electrode 70 functions as a reflective layer. Therefore, it is preferable to form it across most or all of the growth mask 21. Introducing PSS (Patterned Sapphire Substrate) technology on the growth substrate 10 can further ensure optimal mixing of emitted light within the device.

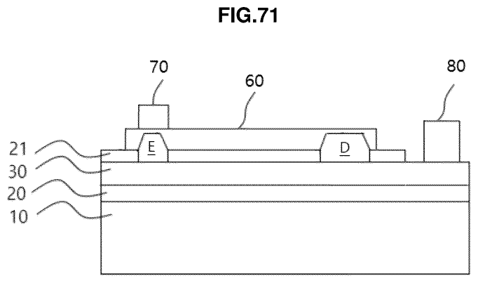

FIG. 71 illustrates another III-nitride semiconductor light emitting device structure. Unlike previous examples, it replaces reflective metal with a current spreading electrode 60, onto which the first electrode 70 is formed, implementing a lateral chip rather than a flip-chip. Removing the growth substrate 10 enables the realization of a vertical chip. The growth mask or insulation layer 21 is positioned beneath the current spreading electrode 60, and additional passivation layers can be included. Although FIG. 71 depicts the first electrode 70 positioned over semiconductor light emitting unit E, potentially obstructing its emission, actual devices may include multiple semiconductor light emitting units E and D, as illustrated in FIG. 32. This prevents significant light blocking issues. Additionally, the placement of the first electrode 70 can be optimized based on these considerations.

Various exemplary embodiments of the present disclosure are described below.
(1) A method for manufacturing a III-nitride semiconductor light-emitting structure that emits red light with a peak wavelength of 600 nm or more, comprising the steps of growing a first superlattice region formed by the repeated stacking of a first sublayer and a second sublayer, and growing an active region on the first superlattice region, which consists of a third sublayer made of an Al-containing III-nitride semiconductor with a first bandgap energy, a fourth sublayer made of an In-containing III-nitride semiconductor with a second bandgap energy smaller than the first bandgap energy, and a fifth sublayer made of an Al-containing III-nitride semiconductor with a third bandgap energy larger than the second bandgap energy. During the active region growth step, setting the In content of the fourth sublayer so that it emits light with a peak wavelength of 600 nm or less when the third and fifth sublayers are GaN, and adjusting the Al content in the third and fifth sublayers so that the fourth sublayer emits red light with a peak wavelength of 600 nm or more.
(2) A method for manufacturing a III-nitride semiconductor light-emitting structure in which the active region includes a quantum well structure, where the fourth sublayer functions as a quantum well layer and the third and fifth sublayers serve as quantum barrier layers. (See FIG. 3)
(3) A method for manufacturing a III-nitride semiconductor light-emitting structure by initially decreasing and then increasing the supply of In during the growth of the fourth sublayer. (See FIG. 4)
(4) A method for manufacturing a III-nitride semiconductor light-emitting structure in which the third, fourth, and fifth sublayers are sequentially grown multiple times, and the topmost fifth sublayer contains InGaN to shift the overall peak emission wavelength of the active region toward longer wavelengths. (See FIG. 5)
(5) A method for manufacturing a III-nitride semiconductor light-emitting structure in which the topmost fifth sublayer is composed of InGaN—GaN.
(6) A method for manufacturing a III-nitride semiconductor light-emitting structure in which the third and fifth sublayers are composed of AlGaN—GaN—AlGaN.
(7) A method for manufacturing a III-nitride semiconductor light-emitting structure in which the first sublayer has a fourth bandgap energy, the second sublayer has a fifth bandgap energy larger than the fourth bandgap energy, and the second sublayer is composed of AlGaN—(In) GaN, AlGaN—(In) GaN—AlGaN, or (In) GaN—AlGaN. (See FIG. 11(c))
(8) A method for manufacturing a III-nitride semiconductor light-emitting structure in which the Al content of AlGaN in the second sublayer is greater than the Al content in the third and fifth sublayers.
(9) A method for manufacturing a III-nitride semiconductor light-emitting structure in which the active region includes a superlattice structure. (See Table 7)
(10) A method for manufacturing a III-nitride semiconductor light-emitting structure in which the third and fifth sublayers are composed of GaN—AlGaN. (See FIG. 17(b))
(11) A III-nitride semiconductor light-emitting device comprising an active region that emits red light and a semi-polar plane positioned below the active region for its growth.
(12) A III-nitride semiconductor light-emitting device in which the active region grows on a rough surface composed of semi-polar planes.
(13) A III-nitride semiconductor light-emitting device including a superlattice region with a rough surface.
(14) A III-nitride semiconductor light-emitting device in which the superlattice region has an AlGaN—InGaN interface.
(15) A III-nitride semiconductor light-emitting device including an additional superlattice region below the superlattice region.
(16) A III-nitride semiconductor light-emitting device including a lateral growth enhancement layer positioned between the superlattice region and the additional superlattice region.
(17) A III-nitride semiconductor light-emitting device including a strain control region below the superlattice region.
(18) A method for measuring a III-nitride semiconductor light-emitting device, comprising the steps of forming a first III-nitride semiconductor light-emitting unit with an active region that emits first light, forming a second III-nitride semiconductor light-emitting unit that emits second light different from the first light, creating a conductive pad extending from the first semiconductor region to the second III-nitride semiconductor light-emitting unit, and using first and second measurement electrodes to measure the electroluminescence (EL) of the first III-nitride semiconductor light-emitting unit.
(19) A method for measuring a III-nitride semiconductor light-emitting device in which a first insulation layer is positioned between the first and second light-emitting units.
(20) A method for measuring a III-nitride semiconductor light-emitting device by applying a first current to measure the EL of the first light-emitting unit, then applying a higher second current to measure the EL of both the first and second light-emitting units.
(21) A method for measuring a III-nitride semiconductor light-emitting device in which the first light is red.
(22) A method for manufacturing a III-nitride semiconductor light-emitting device comprising selectively growing a first semiconductor light-emitting unit using a first opening, selectively growing a second semiconductor light-emitting unit using a larger second opening, and configuring the first semiconductor light-emitting unit to emit blue light while the second semiconductor light-emitting unit emits a longer wavelength light than blue.
(23) A method for manufacturing a III-nitride semiconductor light-emitting device in which the second semiconductor light-emitting unit emits light complementary to blue.
(24) A method for manufacturing a III-nitride semiconductor light-emitting device in which a third semiconductor light-emitting unit is selectively grown using a larger third opening.
(25) A method for manufacturing a III-nitride semiconductor light-emitting device in which selective growth occurs through a single growth mask.
(26) A method for manufacturing a III-nitride semiconductor light-emitting device in which multiple electrodes are formed, and a single growth mask functions as an insulation layer between them.
(27) A method for manufacturing a III-nitride semiconductor light-emitting device in which a first semiconductor light-emitting unit is selectively grown using a first opening, a second semiconductor light-emitting unit is selectively grown using a larger second opening, the first and second openings are formed in a single growth mask, and the growth mask serves as a passivation layer while at least one electrode is formed to supply power.
(28) A method for manufacturing a III-nitride semiconductor light-emitting device in which the first and second semiconductor light-emitting units emit complementary colors, producing white light.
(29) A method for manufacturing a III-nitride semiconductor light-emitting device in which a third semiconductor light-emitting unit is grown before forming electrodes, and the first semiconductor light-emitting unit emits one of blue, green, or red, the second semiconductor light-emitting unit emits another of the remaining two, and the third semiconductor light-emitting unit emits the last color, resulting in white light emission.
(30) A III-nitride semiconductor light emitting device comprising a first semiconductor region having a first conductivity, a second semiconductor region having a second conductivity different from the first conductivity, and an active region interposed between the first and second semiconductor regions, where the active region emits light through electron-hole recombination. The active region includes a quantum well layer with an indium (In) content (x) corresponding to an emission wavelength below 500 nm and an emission region that emits light with a wavelength exceeding 600 nm.
(31) A III-nitride semiconductor light emitting device in which the active region has a quantum well layer with an indium (In) content (x) corresponding to an emission wavelength below 600 nm.
(32) A III-nitride semiconductor light-emitting device in which the indium (In) content (x) ranges from 0.1 to 0.2.
(33) A III-nitride semiconductor light-emitting device including a semi-polar plane for the growth of the active region between the first semiconductor region and the active region.
(34) A III-nitride semiconductor light-emitting device in which the active region emits light through tunneling injection.

According to a III-nitride semiconductor light-emitting device and its manufacturing method disclosed herein, it enables the practical implementation of a III-nitride semiconductor light-emitting device that emits red light.

According to another III-nitride semiconductor light-emitting device and its manufacturing method disclosed herein, it provides a III-nitride semiconductor light-emitting device capable of emitting multiple wavelengths of light and a method for manufacturing such a device.

According to a measurement method for the III-nitride semiconductor light-emitting device disclosed herein, it facilitates the measurement of the electroluminescence of the topmost light-emitting unit in a device with multiple emission layers.

According to another III-nitride semiconductor light-emitting device and its manufacturing method disclosed herein, it enables the implementation of white light using multiple semiconductor light-emitting units grown on a single growth substrate.

What is claimed is:

1. A III-nitride semiconductor light emitting device comprising:
a first semiconductor region having a first conductivity;
a second semiconductor region having a second conductivity different from the first conductivity; and
an active region interposed between the first and second semiconductor regions and generating light through electron-hole recombination wherein the active region includes a quantum well layer with an indium (In) content (x) corresponding to an emission wavelength below 500 nm and emits light with a wavelength exceeding 600 nm.

2. The device of claim 1, wherein the quantum well layer in the active region has an indium (In) content (x) corresponding to an emission wavelength below 600 nm.

3. The device of claim 1, wherein the indium (In) content (x) ranges from 0.1 to 0.2.

4. The device of claim 1, wherein a semi-polar plane for the growth of the active region is included between the first semiconductor region and the active region.

5. The device of claim 1, wherein the active region emits light through tunneling injection.
